(19) United States
(12) Patent Application Publication
(10) Pub. No.: US 2022/0274863 A1
(43) Pub. Date: Sep. 1, 2022

(54) GLASS FILM AND GLASS ROLL USING SAME

(71) Applicant: Nippon Electric Glass Co., Ltd., Shiga (JP)

(72) Inventor: Ryota SUZUKI, Shiga (JP)

(21) Appl. No.: 17/628,740

(22) PCT Filed: Jul. 21, 2020
(86) PCT No.: PCT/JP2020/028302

§ 371 Date: Jan. 20, 2022

(30) Foreign Application Priority Data
Aug. 1, 2019 (JP) 2019-142181
Sep. 13, 2019 (JP) 2019-167014

(51) Int. Cl. C03C 3/091; C03B 17/06; C03C 23/00; C03C 15/00

(52) U.S. Cl. CPC C03C 3/091; C03B 17/064; C03C 23/0025; C03C 15/00

(57) ABSTRACT

Provided is a material which is excellent in heat resistance and weather resistance while having low dielectric characteristics and flexibility. A glass film of the present invention is a glass film, which has a film thickness of 100 μm or less, wherein the glass film has a specific dielectric constant at 25° C. and a frequency of 2.45 GHz of 5 or less and a dielectric dissipation factor at 25° C. and a frequency of 2.45 GHz of 0.01 or less.

### TECHNICAL FIELD

The present invention relates to a glass film and a glass roll using the same, and more specifically, to a glass film and a glass roll using the same, which are suitable for a high-frequency device application.

### BACKGROUND ART

Currently, developments are being made to adapt to the fifth-generation mobile communications system (5G), and technical investigations are underway for allowing the system to achieve higher speed, higher transmission capacity, and lower latency.

For example, in Patent Literature 1, there is a disclosure that through holes for arranging electrical signal paths are formed in a thickness direction of a glass sheet. Specifically, there is a disclosure that the glass sheet is irradiated with a laser to form etch paths, and then a plurality of through holes extending from a major surface of the glass sheet are formed along the etch paths using a hydroxide-based etching material. In addition, the glass sheet described in Patent Literature 1 can also be used for a high-frequency device for 5G communications.

In addition, in Patent Literature 2, there is a disclosure of a laminate formed mainly of an organic compound, including a thermosetting resin layer and a polyimide layer, for the purpose of being used as a high-frequency flexible printed circuit board.

### CITATION LIST

Patent Literature 1: JP 2018-531205 A

Patent Literature 2: JP 2019-014062 A

### SUMMARY OF INVENTION

### Technical Problem

Incidentally, a radio wave having a frequency of several GHz or more is used in 5G communications. In addition, a material to be used for a high-frequency device for 5G communications is required to have low dielectric characteristics in order to reduce the loss of a transmission signal.

However, the glass sheet described in Patent Literature 1 does not have low dielectric characteristics and flexibility, and hence cannot satisfy the above-mentioned need.

In addition, although the laminate of Patent Literature 2 has low dielectric characteristics and flexibility, the laminate is insufficient in heat resistance and weather resistance, and hence cannot secure reliability of a high-frequency device for a long period of time.

The present invention has been made in view of the above-mentioned circumstances, and a technical object of the present invention is to provide a material which is excellent in heat resistance and weather resistance while having low dielectric characteristics and flexibility.

### Solution to Problem

The inventor of the present invention has repeated various experiments, and as a result, has found that the above-mentioned technical object can be achieved by using a predetermined glass film. The finding is proposed as the present invention. That is, according to one embodiment of the present invention, there is provided a glass film, which has a film thickness of 100 μm or less, wherein the glass film has a specific dielectric constant at 25° C. and a frequency of 2.45 GHz of 5 or less and a dielectric dissipation factor at 25° C. and a frequency of 2.45 GHz of 0.01 or less. When the glass film having a film thickness of 100 μm or less is used, the glass film can be improved in heat resistance and weather resistance while having flexibility. In addition, when the dielectric characteristics thereof are restricted as described above, a transmission loss at the time of the transmission of an electrical signal to a high-frequency device can be reduced. Herein, the “specific dielectric constant at 25° C. and a frequency of 2.45 GHz” and the “dielectric dissipation factor at 25° C. and a frequency of 2.45 GHz” may be measured, for example, by a well-known cavity resonator method.

In addition, according to one embodiment of the present invention, there is provided a glass film, which has a film thickness of 100 μm or less, wherein the glass film has a specific dielectric constant at 25° C. and a frequency of 10 GHz of 5 or less and a dielectric dissipation factor at 25° C. and a frequency of 10 GHz of 0.01 or less.

In addition, in the glass film according to the embodiments of the present invention, it is preferred that the glass film have a film thickness of less than 50 μm.

In addition, in the glass film according to the embodiments of the present invention, it is preferred that the glass film comprise as a glass composition, in terms of mass %, 50% to 72% of SiO₂, 0% to 22% of Al₂O₃, 15% to 38% of B₂O₃, 0% to 3% of Li₂O+Na₂O+K₂O, and 0% to 12% of MgO+CaO+SrO+BaO. When the content of B₂O₃ in the glass composition is restricted to 15 mass % or more, the specific dielectric constant and the dielectric dissipation factor can be reduced. Further, when the content of Li₂O+Na₂O+K₂O and the content of MgO+CaO+SrO+BaO in the glass composition are restricted to 3 mass % or less and 12 mass % or less, respectively, a reduction in density is easily achieved, and hence a reduction in weight of a high-frequency device is easily achieved.

In addition, in the glass film according to the embodiments of the present invention, it is preferred that the glass film comprise as the glass composition, in terms of mass %, 50% to 72% of SiO₂, 0.3% to 10.9% of Al₂O₃, 18.1% to 38% of B₂O₃, 0.001% to 3% of Li₂O+Na₂O+K₂O, and 0% to 12% of MgO+CaO+SrO+BaO. In the glass composition, the “A+B+C” refers to the total content of a component A, a component B, and a component C. For example, the “Li₂O+Na₂O+K₂O” refers to the total content of Li₂O, Na₂O, and K₂O. The “MgO+CaO+SrO+BaO” refers to the total content of MgO, CaO, SrO, and BaO.

In addition, in the glass film according to the embodiments of the present invention, it is preferred that the glass film have a mass ratio (MgO+CaO+SrO+BaO)/(SiO₂+Al₂O₃+B₂O₃) of from 0.001 to 0.4. Herein, the “(MgO+CaO+SrO+BaO)/(SiO₂+Al₂O₃+B₂O₃)” refers to a value obtained by dividing the content of MgO+CaO+SrO+BaO by the content of SiO₂+Al₂O₃+B₂O₃.

In addition, in the glass film according to the embodiments of the present invention, it is preferred that the glass film have a plurality of through holes formed in a thickness direction. With this configuration, a wiring structure for establishing conduction between both surfaces of the glass film can be formed, and hence its application to a high-frequency device is facilitated.

In addition, in the glass film according to the embodiments of the present invention, it is preferred that the through holes have an average inner diameter of 300 μm or less. With this configuration, the density of the wiring structure for establishing conduction between both surfaces of the glass film can be easily increased.

In addition, in the glass film according to the embodiments of the present invention, it is preferred that a difference between a maximum value and a minimum value of inner diameters of the through holes be 50 μm or less. With this configuration, a situation in which wiring for establishing conduction between both surfaces of the glass film is improperly lengthened can be prevented, and hence the transmission loss can be reduced.

In addition, in the glass film according to the embodiments of the present invention, it is preferred that a maximum length of a crack in a surface direction extending from the through holes be 100 μm or less. With this configuration, at the time of the production of a high-frequency device, a situation in which the glass film is broken through extension of the crack upon application of a tensile stress around the through holes can be easily prevented. Herein, the “maximum length of a crack in a surface direction extending from the through holes” is a value obtained by measuring a length along the shape of the crack in the observation of the through holes from the front and back surface directions of the glass film with an optical microscope, and is not a value obtained by measuring the length of a distance between two points, connecting the start point and the end point of the crack, nor a value obtained by measuring the length of a crack in a thickness direction.

In addition, in the glass film according to the embodiments of the present invention, it is preferred that the glass film have a Young's modulus of 70 GPa or less. With this configuration, the glass film is easily bent, and is hence easily taken up into a roll shape. In addition, its application to a flexible printed circuit board is facilitated. Herein, the “Young's modulus” may be measured, for example, by a well-known resonance method.

In addition, in the glass film according to the embodiments of the present invention, it is preferred that the glass film have a thermal shrinkage rate of 30 ppm or less in a case in which the glass film is increased in temperature at a rate of 5° C./min, kept at 500° C. for 1 hour, and decreased in temperature at a rate of 5° C./min. With this configuration, the glass film is less liable to be thermally shrunk in a heat treatment step at the time of the production of a high-frequency device, and hence wiring failure can be easily reduced at the time of the production of the high-frequency device. The “thermal shrinkage rate in a case in which the glass film is increased in temperature at a rate of 5° C./min, kept at 500° C. for 1 hour, and decreased in temperature at a rate of 5° C./min” refers to a value measured by the following method. First, a measurement sample is marked with a linear mark at a predetermined position, and then bent perpendicular to the mark to be divided into two glass pieces. Next, one of the glass pieces is subjected to predetermined heat treatment (the glass piece is increased in temperature from normal temperature at a rate of 5° C./min, kept at 500° C. for 1 hour, and decreased in temperature at a rate of 5° C./min). After that, the glass piece having been subjected to the heat treatment and another glass piece not having been subjected to the heat treatment are arranged next to each other, and are fixed with an adhesive tape. Then, a shift between the marks is measured. The thermal shrinkage rate is calculated by the expression ΔL/L₀ (unit: ppm) when the shift between the marks is represented by ΔL and the length of the sample before the heat treatment is represented by L₀.

In addition, in the glass film according to the embodiments of the present invention, it is preferred that the glass film have a thermal expansion coefficient in a temperature range of from 30° C. to 380° C. of from 20×10⁻⁷/° C. to 50×10⁻⁷/° C. With this configuration, warpage or peeling is less liable to occur when a low-expansion member, such as silicon, is bonded to the glass film, and hence its application to a high-frequency device is facilitated. Herein, the “thermal expansion coefficient” may be measured, for example, with a dilatometer.

In addition, in the glass film according to the embodiments of the present invention, it is preferred that the glass film have a value obtained by subtracting a thermal expansion coefficient in a temperature range of from 20° C. to 200° C. from a thermal expansion coefficient in a temperature range of from 20° C. to 300° C. of 1.0×10⁻⁷/° C. or less. With this configuration, even when a heat treatment temperature is changed in the manufacturing process of a high-frequency device, a change in thermal expansion coefficient of the glass film in the respective temperature ranges can be reduced. As a result, the warpage of the high-frequency device due to a difference in thermal expansion coefficient from a low-expansion member, such as silicon, bonded to the glass film can be reduced. Thus, the yield of the high-frequency device can be increased.

In addition, in the glass film according to the embodiments of the present invention, it is preferred that the glass film have an external transmittance at a wavelength of 355 nm in terms of a thickness of 1.0 mm of 80% or more. Herein, the “external transmittance at a wavelength of 355 nm” may be measured with a commercially available spectrophotometer (e.g., V-670 manufactured by JASCO Corporation) using a measurement sample obtained by polishing both surfaces into optically polished surfaces (mirror surfaces).

In addition, in the glass film according to the embodiments of the present invention, it is preferred that the glass film have an external transmittance at a wavelength of 265 nm in terms of a thickness of 1.0 mm of 15% or more. Herein, the “external transmittance at a wavelength of 265 nm” may be measured with a commercially available spectrophotometer (e.g., V-670 manufactured by JASCO Corporation) using a measurement sample obtained by polishing both surfaces into optically polished surfaces (mirror surfaces).

In addition, in the glass film according to the embodiments of the present invention, it is preferred that the glass film have a liquidus viscosity of 10^{4.0} dPa·s or more. With this configuration, the glass is less liable to devitrify at the time of forming, and hence the manufacturing cost of the glass film can be easily reduced. Herein, the “liquidus viscosity” refers to a value obtained by measuring the viscosity of glass at its liquidus temperature by a platinum sphere pull up method. The “liquidus temperature” refers to a value obtained by measuring a temperature at which a crystal precipitates after glass powder that passes through a standard 30-mesh sieve (500 μm) and remains on a 50-mesh sieve (300 μm) is placed in a platinum boat and kept in a gradient heating furnace for 24 hours.

In addition, in the glass film according to the embodiments of the present invention, it is preferred that the glass film be formed by an overflow down-draw method. With this configuration, the surface accuracy of the glass film can be enhanced. In addition, the manufacturing cost of the glass film can be easily reduced.

In addition, in the glass film according to the embodiments of the present invention, it is preferred that the glass film be used as a substrate for a high-frequency device.

In addition, according to one embodiment of the present invention, there is provided a glass roll, which is obtained by taking up a glass film into a roll shape, wherein the glass film is the above-mentioned glass film.

### DESCRIPTION OF EMBODIMENTS

A glass film of the present invention preferably has the following characteristics.

A film thickness is 100 μm or less, preferably 90 μm or less, 80 μm or less, 70 μm or less, 60 μm or less, 50 μm or less, less than 50 μm, 45 μm or less, 40 μm or less, or 35 μm or less, particularly preferably 30 μm or less. When the film thickness is excessively large, the flexibility of the glass film cannot be secured. In addition, the film thickness is preferably 0.1 μm or more, 0.5 μm or more, 1 μm or more, or 2 μm or more, particularly preferably 3 μm or more. When the film thickness is excessively small, the glass film is liable to be broken, and its handling becomes difficult.

A specific dielectric constant at 25° C. and a frequency of 2.45 GHz is preferably 5.0 or less, 4.9 or less, 4.8 or less, 4.7 or less, or 4.6 or less, particularly preferably 4.5 or less. When the specific dielectric constant at 25° C. and a frequency of 2.45 GHz is excessively high, a transmission loss at the time of the transmission of an electrical signal to a high-frequency device is liable to be increased.

A dielectric dissipation factor at 25° C. and a frequency of 2.45 GHz is preferably 0.01 or less, 0.009 or less, 0.008 or less, 0.007 or less, 0.006 or less, 0.005 or less, or 0.004 or less, particularly preferably 0.003 or less. When the dielectric dissipation factor at 25° C. and a frequency of 2.45 GHz is excessively high, the transmission loss at the time of the transmission of an electrical signal to a high-frequency device is liable to be increased.

A specific dielectric constant at 25° C. and a frequency of 10 GHz is preferably 5.0 or less, 4.9 or less, 4.8 or less, 4.7 or less, or 4.6 or less, particularly preferably 4.5 or less. When the specific dielectric constant at 25° C. and a frequency of 10 GHz is excessively high, the transmission loss at the time of the transmission of an electrical signal to a high-frequency device is liable to be increased.

A dielectric dissipation factor at 25° C. and a frequency of 10 GHz is preferably 0.01 or less, 0.009 or less, 0.008 or less, 0.007 or less, 0.006 or less, 0.005 or less, or 0.004 or less, particularly preferably 0.003 or less. When the dielectric dissipation factor at 25° C. and a frequency of 10 GHz is excessively high, the transmission loss at the time of the transmission of an electrical signal to a high-frequency device is liable to be increased.

The glass film of the present invention comprises as a glass composition, in terms of mass %, about 50% to about 72% of SiO₂, about 0% to about 22% of Al₂O₃, about 15% to about 38% of B₂O₃, about 0% to about 3% of Li₂O+Na₂O+K₂O, and about 0% to about 12% of MgO+CaO+SrO+BaO. The reasons why the contents of the components are limited as described above are described below. In the following description, the expression “%” represents “mass %” unless otherwise stated. In addition, in the following description, the “A %” means about A %. For example, the “5%” means about 5%.

The content of SiO₂ is preferably from 50% to 72%, from 53% to 71%, from 55% to 70%, from 57% to 69.5%, from 58% to 69%, from 59% to 70%, or from 60% to 69%, particularly preferably from 62% to 67%. When the content of SiO₂ is excessively small, the specific dielectric constant and the dielectric dissipation factor are liable to be increased, and a density is liable to be increased. Meanwhile, when the content of SiO₂ is excessively large, a viscosity at high temperature is increased to reduce meltability, and besides, a devitrified crystal, such as cristobalite, is liable to precipitate at the time of forming.

Al₂O₃ is a component that increases a Young's modulus, and is also a component for maintaining weather resistance by suppressing phase separation. Accordingly, the lower limit range of Al₂O₃ is preferably 0% or more, 0.1% or more, 0.2% or more, 0.3% or more, 0.4% or more, 0.5% or more, 1% or more, 2% or more, 3% or more, 4% or more, or 5% or more, particularly preferably 6% or more. Meanwhile, when the content of Al₂O₃ is excessively large, a liquidus temperature becomes high, and hence devitrification resistance is liable to be reduced. Accordingly, the upper limit range of Al₂O₃ is preferably 22% or less, 20% or less, 19% or less, 18% or less, 17% or less, 15% or less, 13% or less, 12% or less, 11% or less, 10.9% or less, 10.8% or less, 10.7% or less, 10.6% or less, 10.5% or less, 10% or less, 9.9% or less, 9.8% or less, 9.7% or less, 9.6% or less, 9.5% or less, 9.4% or less, 9.3% or less, 9.2% or less, 9.1% or less, 9.0% or less, 8.9% or less, 8.7% or less, 8.5% or less, 8.3% or less, 8.1% or less, 8.0% or less, 7.9% or less, 7.8% or less, 7.7% or less, 7.6% or less, 7.5% or less, 7.3% or less, or 7.1% or less, particularly preferably 7.0% or less.

B₂O₃ is a component that reduces the specific dielectric constant and the dielectric dissipation factor. Accordingly, the lower limit range of B₂O₃ is preferably 15% or more, 18% or more, 18.1% or more, 18.2% or more, 18.3% or more, 18.4% or more, 18.5% or more, 19% or more, 19.4% or more, 19.5% or more, 19.6% or more, 20% or more, more than 20%, 22% or more, 24% or more, 25% or more, 25.1% or more, 25.3% or more, or 25.5% or more, particularly preferably 25.6% or more. Meanwhile, when the content of B₂O₃ is excessively large, heat resistance and chemical durability are reduced, and the weather resistance is liable to be reduced through phase separation. In addition, the density and the viscosity at high temperature are liable to be increased. Accordingly, the upper limit range of B₂O₃ is preferably 38% or less, 35% or less, 33% or less, 32% or less, 31% or less, 30% or less, or 28% or less, particularly preferably 27% or less.

The content of B₂O₃—Al₂O₃ is preferably-5% or more, -4% or more, -3% or more, -2% or more, -1% or more, 0% or more, 1% or more, 2% or more, 3% or more, 4% or more, 5% or more, 6% or more, 7% or more, 8% or more, or 9% or more, particularly preferably 10% or more. When the content of B₂O₃—Al₂O₃ is excessively small, low dielectric characteristics are difficult to secure. The “B₂O₃—Al₂O₃” refers to an amount obtained by subtracting the content of Al₂O₃ from the content of B₂O₃.

Alkali metal oxides are components that enhance the meltability and formability, but when the contents thereof are excessively large, the density is increased, water resistance is reduced, and a thermal expansion coefficient is improperly increased, with the result that thermal shock resistance is reduced, and that it is difficult for the thermal expansion coefficient to match those of peripheral materials. In addition, the low dielectric characteristics are difficult to secure. Accordingly, the content of Li₂O+Na₂O+K₂O is preferably from 0% to 3%, from 0% to 2%, from 0% to 1%, from 0% to 0.5%, from 0% to 0.2%, or from 0% to 0.1%, particularly preferably from 0.001% to less than 0.05%. The content of each of Li₂O, Na₂O, and K₂O is preferably from 0% to 3%, from 0% to 2%, from 0% to 1%, from 0% to 0.5%, from 0% to 0.2%, or from 0% to 0.1%, particularly preferably from 0.001% to less than 0.01%.

Alkaline earth metal oxides are components that reduce the liquidus temperature to make a devitrified crystal less liable to be generated in the glass, and are also components that enhance the meltability and the formability. The content of MgO+CaO+SrO+BaO is preferably from 0% to 12%, from 0% to 10%, from 0% to 8%, from 0% to 7%, from 1% to 7%, from 2% to 7%, or from 3% to 9%, particularly preferably from 3% to 6%. When the content of MgO+CaO+SrO+BaO is excessively small, the devitrification resistance is liable to be reduced, and besides, their function as melting accelerate components cannot be sufficiently exhibited, with the result that the meltability is liable to be reduced. Meanwhile, when the content of MgO+CaO+SrO+BaO is excessively large, the density is increased to make it difficult to achieve a reduction in weight of the glass, and besides, the thermal expansion coefficient is improperly increased, with the result that the thermal shock resistance is liable to be reduced. In addition, the low dielectric characteristics are difficult to secure.

MgO is a component that reduces the viscosity at high temperature to enhance the meltability without reducing a strain point, and is also a component that is least liable to increase the density among the alkaline earth metal oxides. The content of MgO is preferably from 0% to 12%, from 0% to 10%, from 0.01% to 8%, from 0.1% to 6%, from 0.2% to 5%, from 0.3% to 4%, or from 0.5% to 3%, particularly preferably from 1% to 2%. However, when the content of MgO is excessively large, the liquidus temperature is increased, and hence the devitrification resistance is liable to be reduced. In addition, the glass undergoes phase separation, and hence its transparency is liable to be reduced.

CaO is a component that reduces the viscosity at high temperature to remarkably enhance the meltability without reducing the strain point, and is also a component that has a great effect of enhancing the devitrification resistance in the glass composition system of the present invention. Accordingly, a suitable lower limit range of CaO is 0% or more, 0.05% or more, 0.1% or more, 1% or more, 1.1% or more, 1.2% or more, 1.3% or more, 1.4% or more, or 1.5% or more, particularly 2% or more. Meanwhile, when the content of Cao is excessively large, the thermal expansion coefficient and the density are improperly increased, and the glass composition loses its component balance, with the result that the devitrification resistance is liable to be reduced contrarily. Accordingly, a suitable upper limit range of Cao is 12% or less, 10% or less, 8% or less, 7% or less, 6% or less, 5% or less, 4.6% or less, 4.5% or less, 4.4% or less, or 4% or less, particularly 3% or less.

SrO is a component that reduces the viscosity at high temperature to enhance the meltability without reducing the strain point, but when the content of SrO is excessively large, a liquidus viscosity is liable to be reduced. Accordingly, the content of SrO is preferably from 0 to 10%, from 0% to 8%, from 0% to 7%, from 0% to 6%, from 0% to 5.1%, from 0% to 5%, from 0% to 4.9%, from 0% to 4%, from 0% to 3%, from 0% to 2%, from 0% to 1.5%, from 0% to 1%, or from 0% to 0.5%, particularly preferably from 0.01% to 0.1%.

BaO is a component that reduces the viscosity at high temperature to enhance the meltability without reducing the strain point, but when the content of BaO is excessively large, the liquidus viscosity is liable to be reduced. Accordingly, the content of BaO is preferably from 0% to 10%, from 0% to 8%, from 0% to 7%, from 0% to 6%, from 0% to 5%, from 0% to 4%, from 0% to 3%, from 0% to 2%, from 0% to 1.5%, from 0% to 1%, or from 0% to 0.5%, particularly preferably from 0% to less than 0.1%.

When a mass ratio (MgO+CaO+SrO+BaO)/(SiO₂+Al₂O₃+B₂O₃) is excessively large, low melting point characteristics are difficult to secure, and besides, in the formation of through holes by etching, an etching rate tends to be increased to distort the shapes of the through holes. Further, also in the formation of through holes by laser irradiation, hole-making accuracy tends to be reduced. Meanwhile, when the mass ratio (MgO+CaO+SrO+BaO)/(SiO₂+Al₂O₃+B₂O₃) is excessively small, the viscosity at high temperature is increased to increase a melting temperature, and hence the manufacturing cost of the glass film is liable to rise. Accordingly, the mass ratio (MgO+CaO+SrO+BaO)/(SiO₂+Al₂O₃+B₂O₃) is preferably from 0.001 to 0.4, from 0.005 to 0.35, from 0.010 to 0.30, from 0.020 to 0.25, from 0.030 to 0.20, from 0.035 to 0.15, from 0.040 to 0.14, or from 0.045 to 0.13, particularly preferably from 0.050 to 0.10.

When a mass ratio (MgO+CaO+SrO+BaO)/Al₂O₃ is excessively small, the devitrification resistance is reduced to make it difficult to form a film shape by an overflow down-draw method. Meanwhile, when the mass ratio (MgO+CaO+SrO+BaO)/Al₂O₃ is excessively large, there is a risk in that the density and the thermal expansion coefficient may be improperly increased. Accordingly, the mass ratio (MgO+CaO+SrO+BaO)/Al₂O₃ is preferably from 0.1 to 1.5, from 0.1 to 1.2, from 0.2 to 1.2, from 0.3 to 1.2, or from 0.4 to 1.1, particularly preferably from 0.5 to 1.0. The “(MgO+CaO+SrO+BaO)/Al₂O₃” refers to a value obtained by dividing the content of MgO+CaO+SrO+BaO by the content of Al₂O₃.

A mass ratio (SrO+BaO)/B₂O₃ is preferably 0.5 or less, 0.4 or less, 0.3 or less, 0.2 or less, 0.1 or less, 0.05 or less, or 0.03 or less, particularly preferably 0.02 or less. When the mass ratio (SrO+BaO)/B₂O₃ is excessively large, the low dielectric characteristics are difficult to secure, and besides, the liquidus viscosity is difficult to increase. The “SrO+BaO” refers to the total content of SrO and BaO. In addition, the “(SrO+BaO)/B₂O₃” refers to a value obtained by dividing the content of SrO+BaO by the content of B₂O₃.

A mass ratio B₂O₃/(SrO+BaO) is preferably 2 or more, 5 or more, 10 or more, 20 or more, 30 or more, or 40 or more, particularly preferably 50 or more. When the mass ratio (SrO+BaO)/B₂O₃ is excessively small, the low dielectric characteristics are difficult to secure, and besides, the liquidus viscosity is difficult to increase. The “B₂O₃/(SrO+BaO)” refers to a value obtained by dividing the content of B₂O₃ by the content of SrO+BaO. The “B₂O₃/(SrO+BaO)” refers to a value obtained by dividing the content of B₂O₃ by the content of SrO+BaO.

B₂O₃—(MgO+CaO+SrO+BaO) is preferably 5% or more, 6% or more, 7% or more, 8% or more, 9% or more, 10% or more, or 11% or more, particularly preferably 12% or more. When the content of B₂O₃—(MgO+CaO+SrO+BaO) is excessively small, the low dielectric characteristics are difficult to secure, and besides, the density is liable to be increased. In addition, the Young's modulus is liable to be reduced. The “B₂O₃— (MgO+CaO+SrO+BaO)” refers to a value obtained by subtracting the content of MgO+CaO+SrO+BaO from the content of B₂O₃.

A mass ratio (SrO+BaO)/(MgO+CaO) is preferably 400 or less, 300 or less, 100 or less, 50 or less, 10 or less, 5 or less, 2 or less, 1 or less, 0.8 or less, or 0.5 or less, particularly preferably 0.3 or less. When the mass ratio (SrO+BaO)/(MgO+CaO) is excessively large, the low dielectric characteristics are difficult to secure, and besides, the density is liable to be increased. The “(SrO+BaO)/(MgO+CaO)” refers to a value obtained by dividing the content of SrO+BaO by the content of MgO+CaO.

In addition to the above-mentioned components, the following components may be introduced into the glass composition.

ZnO is a component that enhances the meltability, but when a large amount thereof is contained in the glass composition, the glass is liable to devitrify, and besides, the density is liable to be increased. Accordingly, the content of ZnO is preferably from 0% to 5%, from 0% to 3%, from 0% to 0.5%, or from 0% to 0.3%, particularly preferably from 0% to 0.1%.

ZrO₂ is a component that enhances the weather resistance. The content of ZrO₂ is preferably from 0% to 5%, from 0% to 3%, from 0% to 0.5%, from 0% to 0.2%, from 0% to 0.16%, or from 0% to 0.1%, particularly preferably from 0% to 0.02%. When the content of ZrO₂ is excessively large, the liquidus temperature is increased, with the result that a devitrified crystal of zircon is liable to precipitate.

TiO₂ is a component that reduces the viscosity at high temperature to enhance the meltability, but when a large amount thereof is contained in the glass composition, the glass is liable to be colored to be reduced in transmittance. Accordingly, the content of TiO₂ is preferably from 0% to 5%, from 0% to 3%, from 0% to 1%, or from 0% to 0.1%, particularly preferably from 0% to 0.02%.

P₂O₅ is a component that enhances the devitrification resistance, but when a large amount thereof is contained in the glass composition, the glass is liable to undergo phase separation to opacify, and besides, there is a risk in that the water resistance may be remarkably reduced. Accordingly, the content of P₂O₅ is preferably from 0% to 5%, from 0% to 1%, or from 0% to 0.5%, particularly preferably from 0% to 0.1%.

SnO₂ is a component that has a satisfactory fining action in a high-temperature region, and is also a component that reduces the viscosity at high temperature. The content of SnO₂ is preferably from 0% to 1%, from 0.01% to 0.5%, or from 0.05% to 0.3%, particularly preferably from 0.1% to 0.3%. When the content of SnO₂ is excessively large, a devitrified crystal of SnO₂ is liable to precipitate.

Fe₂O₃ is an impurity component, or a component that may be introduced as a fining agent component. However, when the content of Fe₂O₃ is excessively large, there is a risk in that an ultraviolet light transmittance may be reduced. Accordingly, the content of Fe₂O₃ is preferably 0.05% or less, or 0.03% or less, particularly preferably 0.02% or less. The term “Fe₂O₃” as used in the present invention includes ferrous oxide and ferric oxide, and ferrous oxide is treated in terms of Fe₂O₃. Other polyvalent oxides are also similarly treated with reference to indicated oxides.

SnO₂ is suitably added as a fining agent, but CeO₂, SO₃, C, or metal powder (e.g., Al or Si) may be added as a fining agent up to 1% as long as glass characteristics are not impaired.

As₂O₃, Sb₂O₃, F, and Cl each also effectively act as a fining agent, and the present invention does not exclude the incorporation of those components, but from an environmental point of view, the content of each of those components is preferably less than 0.1%, particularly preferably less than 0.05%.

The glass film of the present invention preferably has the following characteristics.

The Young's modulus is preferably 70 GPa or less, 69 GPa or less, 68 GPa or less, 67 GPa or less, 66 GPa or less, 65 GPa or less, 64 GPa or less, 63 GPa or less, 62 GPa or less, or 61 GPa or less, particularly preferably 60 GPa or less. When the Young's modulus is excessively high, the glass film is hardly bent, and hence it becomes difficult to take up the glass film into a roll shape. In addition, its application to a flexible printed circuit board becomes difficult.

A thermal shrinkage rate in a case in which the glass film is increased in temperature at a rate of 5° C./min, kept at 500° C. for 1 hour, and decreased in temperature at a rate of 5° C./min is preferably 30 ppm or less, 25 ppm or less, or 20 ppm or less, particularly preferably 18 ppm or less. When the thermal shrinkage rate is excessively high, the glass film is liable to be thermally shrunk in a heat treatment step at the time of the production of a high-frequency device, and hence wiring failure is liable to occur at the time of the production of the high-frequency device.

The thermal expansion coefficient in a temperature range of from 30° C. to 380° C. is preferably from 20×10⁻⁷/° C. to 50×10⁻⁷/° C., from 22×10⁻⁷/° C. to 48×10⁻⁷/° C., from 23×10⁻⁷/° C. to 47×10⁻⁷/° C., from 28×10⁻⁷/° C. to 45×10⁻⁷/° C., from 30×10⁻⁷/° C. to 43×10⁻⁷/° C., or from 32×10⁻⁷/° C. to 41×10⁻⁷/° C., particularly preferably from 35×10⁻⁷/° C. to 39×10⁻⁷/° C. When the thermal expansion coefficient in a temperature range of from 30° C. to 380° C. is excessively high, warpage or peeling is liable to occur when a low-expansion member, such as silicon, is bonded to the glass film, and hence its application to a high-frequency device becomes difficult.

The thermal expansion coefficient in a temperature range of from 20° C. to 200° C. is preferably from 21×10⁻⁷/° C. to 51×10⁻⁷/° C., from 22×10⁻⁷/° C. to 48×10⁻⁷/° C., from 23×10⁻⁷/° C. to 47×10⁻⁷/° C., from 25×10⁻⁷/° C. to 46×10⁻⁷/° C., from 28×10⁻⁷/° C. to 45×10⁻⁷/° C., from 30×10⁻⁷/° C. to 43×10⁻⁷/° C., or from 32×10⁻⁷/° C. to 41×10⁻⁷/° C., particularly preferably from 35×10⁻⁷/° C. to 39×10⁻⁷/° C. When the thermal expansion coefficient in a temperature range of from 20° C. to 200° C. falls outside the above-mentioned ranges, a low-expansion member, such as silicon, is difficult to bond to the glass film.

The thermal expansion coefficient in a temperature range of from 20° C. to 220° C. is preferably from 21×10⁻⁷/° C. to 51×10⁻⁷/° C., from 22×10⁻⁷/° C. to 48×10⁻⁷/° C., from 23×10⁻⁷/° C. to 47×10⁻⁷/° C., from 25×10⁻⁷/° C. to 46×10⁻⁷/° C., from 28×10⁻⁷/° C. to 45×10⁻⁷/° C., from 30×10⁻⁷/° C. to 43×10⁻⁷/° C., or from 32×10⁻⁷/° C. to 41×10⁻⁷/° C., particularly preferably from 35×10⁻⁷/° C. to 39×10⁻⁷/° C. When the thermal expansion coefficient in a temperature range of from 20° C. to 220° C. falls outside the above-mentioned ranges, a low-expansion member, such as silicon, is difficult to bond to the glass film.

The thermal expansion coefficient in a temperature range of from 20° C. to 260° C. is preferably from 21×10⁻⁷/° C. to 51×10⁻⁷/° C., from 22×10⁻⁷/° C. to 48×10⁻⁷/° C., from 23×10⁻⁷/° C. to 47×10⁻⁷/° C., from 25×10⁻⁷/° C. to 46×10⁻⁷/° C., from 28×10⁻⁷/° C. to 45×10⁻⁷/° C., from 30×10⁻⁷/° C. to 43×10⁻⁷/° C., or from 32×10⁻⁷/° C. to 41×10⁻⁷/° C., particularly preferably from 35×10⁻⁷/° C. to 39×10⁻⁷/° C. When the thermal expansion coefficient in a temperature range of from 20° C. to 260° C. falls outside the above-mentioned ranges, a low-expansion member, such as silicon, is difficult to bond to the glass film.

The thermal expansion coefficient in a temperature range of from 20° C. to 300° C. is preferably from 20×10⁻⁷/° C. to 50×10⁻⁷/° C., from 22×10⁻⁷/° C. to 48×10⁻⁷/° C., from 23×10⁻⁷/° C. to 47×10⁻⁷/° C., from 25×10⁻⁷/° C. to 46×10⁻⁷/° C., from 28×10⁻⁷/° C. to 45×10⁻⁷/° C., from 30×10⁻⁷/° C. to 43×10⁻⁷/° C., or from 32×10⁻⁷/° C. to 41×10⁻⁷/° C., particularly preferably from 35×10⁻⁷/° C. to 39×10⁻⁷/° C. When the thermal expansion coefficient in a temperature range of from 20° C. to 300° C. falls outside the above-mentioned ranges, a low-expansion member, such as silicon, is difficult to bond to the glass film.

A value obtained by subtracting the thermal expansion coefficient in a temperature range of from 20° C. to 200° C. from the thermal expansion coefficient in a temperature range of from 20° C. to 300° C. is preferably 1.0×10⁻⁷/° C. or less, and is preferably 0.9×10⁻⁷/° C. or less and −1.0×10⁻⁷/° C. or more, −0.8×10⁻⁷/° C. or more and 0.7×10⁻⁷/° C. or less, −0.6×10⁻⁷/° C. or more and 0.5×10⁻⁷/° C. or less, or −0.4×10⁻⁷/° C. or more and 0.3×10⁻⁷/° C. or less, particularly preferably −0.3×10⁻⁷/° C. or more and 0.2×10⁻⁷/° C. or less. With this configuration, even when a heat treatment temperature is changed in the manufacturing process of a high-frequency device, a change in thermal expansion coefficient of the glass film in the respective temperature ranges can be reduced. As a result, the warpage of the high-frequency device due to a difference in thermal expansion coefficient from a low-expansion member, such as silicon, bonded to the glass film can be reduced. Thus, the yield of the high-frequency device can be increased.

An external transmittance at a wavelength of 1,100 nm in terms of a thickness of 1.0 mm is preferably 85% or more, 86% or more, 87% or more, 88% or more, 89% or more, or 90% or more, particularly preferably 91% or more. When the external transmittance at a wavelength of 1,100 nm in terms of a thickness of 1.0 mm falls outside the above-mentioned ranges, for example, in the case in which a resin layer or high-frequency device bonded to the front surface of the glass film is peeled off or cured by being irradiated with an infrared laser or the like from the back surface side of the glass film, there is an increased risk in that the peeling or the curing may be unsuccessful, resulting in a product defect.

An external transmittance at a wavelength of 355 nm in terms of a thickness of 1.0 mm is preferably 80% or more, 81% or more, 82% or more, 83% or more, 84% or more, or 85% or more, particularly preferably 86% or more. When the external transmittance at a wavelength of 355 nm in terms of a thickness of 1.0 mm falls outside the above-mentioned ranges, for example, in the case in which a resin layer or high-frequency device bonded to the front surface of the glass film is peeled off or cured by being irradiated with an infrared laser or the like from the back surface side of the glass film, there is an increased risk in that the peeling or the curing may be unsuccessful, resulting in a product defect.

An external transmittance at a wavelength of 265 nm in terms of a thickness of 1.0 mm is preferably 15% or more, 16% or more, 17% or more, 18% or more, 20% or more, or 22% or more, particularly preferably 23% or more. When the external transmittance at a wavelength of 265 nm in terms of a thickness of 1.0 mm falls outside the above-mentioned ranges, for example, in the case in which a resin layer or high-frequency device bonded to the front surface of the glass film is peeled off or cured by being irradiated with an infrared laser or the like from the back surface side of the glass film, there is an increased risk in that the peeling or the curing may be unsuccessful, resulting in a product defect.

The liquidus viscosity is preferably 10^{3.9} dPa·s or more, 10^{4.0} dPa·s or more, 10^{4.2} dPa·s or more, 10^{4.6} dPa·s or more, 10^{4.8} dPa·s or more, or 10^{5.0} dPa·s or more, particularly preferably 10^{5.2} dPa·s or more. When the liquidus viscosity is excessively low, the glass is liable to devitrify at the time of forming.

The strain point is preferably 480° C. or more, 500° C. or more, 520° C. or more, 530° C. or more, 540° C. or more, 550° C. or more, 560° C. or more, 570° C. or more, or 580° C. or more, particularly preferably 590° C. or more. When the strain point is excessively low, the glass film is liable to be thermally shrunk in a heat treatment step at the time of the production of a high-frequency device, and hence wiring failure is liable to occur at the time of the production of the high-frequency device.

A β-OH value is preferably 1.1 mm⁻¹ or less, 0.6 mm⁻¹ or less, 0.55 mm⁻¹ or less, 0.5 mm⁻¹ or less, 0.45 mm⁻¹ or less, 0.4 mm⁻¹ or less, 0.35 mm⁻¹ or less, 0.3 mm⁻¹ or less, 0.25 mm⁻¹ or less, 0.2 mm⁻¹ or less, or 0.15 mm⁻¹ or less, particularly preferably 0.1 mm⁻¹ or less. When the β-OH value is excessively large, the low dielectric characteristics are difficult to secure. The “13-0H value” is a value calculated by the following equation using FT-IR.

β-OH value=(1/X)log(T₁/T₂)

X: Thickness (mm)

T₁: Transmittance (%) at a reference wavelength of 3,846 cm⁻¹

T₂: Minimum transmittance (%) at a wavelength around a hydroxyl group absorption wavelength of 3,600 cm⁻¹

A fracture toughness K_{1c} is preferably 0.6 MPa·m^{0.5} or more, 0.62 MPa·m^{0.5} or more, 0.65 MPa·m^{0.5} or more, 0.67 MPa·m^{0.5} or more, or 0.69 MPa·m^{0.5} or more, particularly preferably 0.7 MPa·m^{0.5} or more. When the fracture toughness K_{1c} is excessively low, at the time of the production of a high-frequency device, the glass film is liable to be broken through extension of a crack upon application of a tensile stress around the through holes. The “fracture toughness K_{1c}” is measured using a Single-Edge-Precracked-Beam method (SEPB method) on the basis of “Testing methods for fracture toughness of fine ceramics at room temperature” of JIS R1607. The SEPB method is a method involving subjecting a precracked specimen to a three-point bending fracture test to measure the maximum load before fracture of the specimen, and determining a plane-strain fracture toughness K_{1c} from the maximum load, the length of the preformed crack, the dimensions of the specimen, and a distance between bending fulcrums. The measured value of the fracture toughness K_{1c} of each glass is an average value of five measurements.

A volume resistivity Log ρ at 25° C. is preferably 16 Ω·cm or more, 16.5 Ω·cm or more, or 17 Ω·cm or more, particularly preferably 17.5 Ω·cm or more. When the volume resistivity Log ρ at 25° C. is excessively low, a transmission signal is liable to flow to the glass film side, and hence the transmission loss at the time of the transmission of an electrical signal to a high-frequency device is liable to be increased. The “volume resistivity Log ρ at 25° C.” refers to a value measured on the basis of ASTM C657-78.

A thermal conductivity at 25° C. is preferably 0.7 W/(m·K) or more, 0.75 W/(m·K) or more, 0.8 W/(m·K) or more, or 0.85 W/(m·K) or more, particularly preferably 0.9 W/(m·K) or more. When the thermal conductivity at 25° C. is excessively low, the heat dissipating property of the glass film is reduced, and hence there is a risk in that the glass film may undergo an excessive temperature increase during the operation of a high-frequency device. The “thermal conductivity at 25° C.” refers to a value measured on the basis of JIS R2616.

A water vapor transmission rate is preferably 1×10⁻¹ g/(m²·24 h) or less, 1×10⁻² g/(m²·24 h) or less, 1×10⁻³ g/(m²·24 h) or less, or 1×10⁻⁴ g/(m²·24 h) or less, particularly preferably 1×10⁻⁵ g/(m²·24 h) or less. When the water vapor transmission rate is excessively high, the glass film is liable to trap water vapor, and hence the low dielectric characteristics are difficult to maintain. The “water vapor transmission rate” may be measured by a known calcium method.

The glass film of the present invention preferably has a plurality of through holes formed in a thickness direction. In addition, from the viewpoint of increasing a wiring density, the average inner diameter of the through holes is preferably 300 μm or less, 280 μm or less, 250 μm or less, 230 μm or less, 200 μm or less, 180 μm or less, 150 μm or less, 130 μm or less, 120 μm or less, 110 μm or less, or 100 μm or less, particularly preferably 90 μm or less. However, when the average inner diameter of the through holes is excessively small, a wiring structure for establishing conduction between both surfaces of the glass film is difficult to form. Accordingly, the average inner diameter of the through holes is preferably 10 μm or more, 20 μm or more, 30 μm or more, or 40 μm or more, particularly preferably 50 μm or more.

A difference between the maximum value and the minimum value of the inner diameters of the through holes is preferably 50 μm or less, 45 μm or less, 40 μm or less, 35 μm or less, or 30 μm or less, particularly preferably 25 μm or less. When the difference between the maximum value and the minimum value of the inner diameters of the through holes is excessively large, the length of wiring for establishing conduction between both surfaces of the glass film is unnecessarily increased, and hence the transmission loss is difficult to reduce.

The maximum length of a crack in a surface direction extending from the through holes is preferably 100 μm or less, 50 μm or less, 30 μm or less, 10 μm or less, 5 μm or less, 3 μm or less, or 1 μm or less, particularly preferably 0.5 μm or less. When the maximum length of a crack in a surface direction extending from the through holes is excessively large, at the time of the production of a high-frequency device, the glass film is liable to be broken through extension of the crack upon application of a tensile stress around the through holes.

The shape of the glass film is preferably a rectangular shape. With this configuration, its application to the manufacturing process of a flexible printed wiring board is facilitated. The glass film of the present invention has dimensions of preferably 0.5 mm×0.5 mm or more, 1 mmxl mm or more, 5 mm×5 mm or more, 10 mm×10 mm or more, 20 mm×20 mm or more, 25 mm×25 mm or more, 30 mm×30 mm or more, 50 mm×50 mm or more, 100 mm×100 mm or more, 200 mm×200 mm or more, or 300 mm×300 mm or more, particularly preferably 400 mm×400 mm or more. When the dimensions of the glass film are excessively small, it becomes difficult to perform multi-chamfering in the manufacturing process of a high-frequency device, and hence the manufacturing cost of the high-frequency device is liable to rise.

The glass film of the present invention is preferably given individual identification information. With this configuration, in the manufacturing process of a high-frequency device, the manufacturing history and the like of individual glass films can be identified, and hence an investigation of the cause of a product defect can be easily performed. As a method of giving the glass film individual identification information, there are given, for example, a known laser ablation method (evaporation of glass through irradiation with a pulsed laser), barcode printing, and QR code (trademark) printing.

The glass film of the present invention is preferably formed by an overflow down-draw method. With this configuration, a glass film having satisfactory surface quality in an unpolished state can be efficiently obtained. Other than the overflow down-draw method, various forming methods may be adopted. For example, forming methods such as a slot down method, a float method, a roll-out method, and a redraw method may be adopted.

In addition, the glass film of the present invention is preferably used as a substrate for a high-frequency device, and for example, may be used as a substrate fora high-frequency flexible printed circuit board.

From the viewpoint of reducing the resistance loss of a high-frequency device, the arithmetic average roughness Ra of the surface of the glass film is preferably 100 nm or less, 50 nm or less, 20 nm or less, 10 nm or less, 5 nm or less, 2 nm or less, or 1 nm or less, particularly preferably 0.5 nm or less. When the arithmetic average roughness Ra of the surface of the glass film is excessively large, the arithmetic average roughness Ra of metal wiring to be formed on the surface of the glass film is increased, and hence a resistance loss due to a so-called skin effect, which occurs when a current is caused to flow through the metal wiring of a high-frequency device, becomes excessive. In addition, the glass film is reduced in strength, and hence is liable to be broken.

In addition, from the viewpoint of increasing the manufacturing yield of a high-frequency device, the arithmetic average roughness Ra of the surface of the glass film is preferably 1 nm or more, 1.3 nm or more, 1.4 nm or more, 1.5 nm or more, 1.6 nm or more, 1.8 nm or more, 2 nm or more, 4 nm or more, 8 nm or more, 11 nm or more, 15 nm or more, 25 nm or more, 40 nm or more, 60 nm or more, 90 nm or more, 110 nm or more, 200 nm or more, or 300 nm or more, particularly preferably from 400 nm to 3,000 nm. When the arithmetic average roughness Ra of the surface of the glass film is excessively small, metal wiring to be formed on the surface of the glass film and a coating layer covering the surface of the glass film are liable to be peeled off. As a result, the manufacturing yield of the high-frequency device is liable to be reduced. The “arithmetic average roughness Ra” may be measured with a stylus-type surface roughness meter or an atomic force microscope (AFM).

The glass film of the present invention is preferably used in the manufacturing process of a high-frequency device, and is more preferably used in a semi-additive process. When the semi-additive process is adopted, the wiring width of the high-frequency device can be adjusted to the width required of the device.

In addition, the glass film of the present invention is preferably used in a process involving forming passive components on the surface of the glass film. In addition, the passive components preferably include at least one or more kinds of a capacitor, a coil, and a resistor, and for example, a module for an RF front end for a smartphone is preferred.

In the manufacturing process of a high-frequency device, the highest treatment temperature is preferably 350° C. or less, 345° C. or less, 340° C. or less, 335° C. or less, or 330° C. or less, particularly preferably 325° C. or less. When the highest treatment temperature is excessively high, the reliability of the high-frequency device is liable to be reduced.

The glass film of the present invention preferably has the form of a glass roll in which the glass film is taken up into a roll shape. The outer diameter of the glass roll is preferably 50 mm or more, 60 mm or more, 70 mm or more, 80 mm or more, 90 mm or more, 100 mm or more, 200 mm or more, or 300 mm or more. In addition, the width of the glass roll is preferably 5 mm or more, 10 mm or more, 20 mm or more, 30 mm or more, 40 mm or more, 50 mm or more, 100 mm or more, 300 mm or more, 500 mm or more, or 1,000 mm or more. With this configuration, the application of the glass film to a roll-to-roll process is facilitated, and the manufacturing cost of a high-frequency device can be easily reduced.

The glass film is taken up so that the glass roll is in the state of having a minimum radius of curvature of preferably 500 mm or less, 300 mm or less, 150 mm or less, 100 mm or less, 70 mm or less, or 50 mm or less, particularly preferably 30 mm or less. When the glass film is taken up so that the state of having a small minimum radius of curvature is achieved, the packaging efficiency and conveyance efficiency of the glass film are improved.

The glass roll is preferably taken up around a winding core. With this configuration, when the glass film is taken up, the glass film can be fixed to the winding core. As a result, even when an external pressure is applied to the glass roll, the deformation of the glass film is suppressed by the winding core, and hence the breakage of the glass film can be prevented. In addition, the winding core is preferably longer than the width of the glass film in order to prevent a situation in which the glass film is broken from an end surface thereof owing to an external factor. The material of the winding core is not particularly limited, and a thermoplastic resin, a paper core, or the like may be used.

In the glass roll, a buffer film (slip sheet) made of a resin or paper may be inserted between the glass films in order to improve impact resistance, or the end surface of the glass film may be covered with a resin in order to increase mechanical strength, or the end surface of the glass film may be etched to be smoothened.

When the glass roll is obtained by taking up the glass film after scribing an end portion (selvage portion) thereof in a width direction, the glass film is preferably taken up so that a scribe line is located inside. With this configuration, cracks are less liable to occur from the end surface of the glass film. On the contrary, when the glass film is taken up so that the scribe line is located outside, the glass film is liable to be broken upon a tensile stress from a fine flaw occurring at a groove of the scribe line as an origin. Such fine flaw may be reduced by chemical polishing or fire polishing.

The glass roll is preferably obtained by cutting and separating the end portion of the glass film with a laser. With this configuration, after the glass film is formed, the end portion of the glass film can be continuously cut and separated. As a result, the production efficiency of the glass roll is improved, and cracks are less liable to occur from the end surface of the glass film. A carbon dioxide gas laser, a YAG laser, or the like may be used as the laser. The output of the laser is preferably adjusted so that the development speed of cracks progressing with the laser and the sheet-drawing speed of the glass film match each other. In this case, the value for a ratio in speed=(speed of cracks developing with laser−sheet-drawing speed)/(sheet-drawing speed)×100 is preferably ±10% or less, ±5% or less, ±1% or less, ±0.5% or less, or ±0.1% or less.

### EXAMPLES

### Example 1

Now, the present invention is described in detail based on Examples. The following Examples are merely illustrative. The present invention is by no means limited to the following Examples.

Examples of the present invention (Samples No. 1 to 104) are shown in Tables 1 to 13. [Unmeasured] in each of the tables means that no measurement has been performed.

TABLE 1

| | | No. 1 | No. 2 | No. 3 | No. 4 | No. 5 | No. 6 | No. 7 | No. 8 |
|---|---|---|---|---|---|---|---|---|---|
| Composition | SiO₂ | 63.41 | 58.02 | 67.14 | 61.39 | 56.14 | 70.92 | 65.83 | 59.84 |
| (mass %) | Al₂O₃ | 6.5 | 12.7 | 6.5 | 12.7 | 18.5 | 6.5 | 12.8 | 18.6 |
| | B₂O₃ | 25.2 | 24.5 | 21.4 | 21.1 | 20.7 | 17.6 | 16.6 | 16.8 |
| | Na₂O | 0.02 | 0.02 | 0.02 | 0.02 | 0.02 | 0.03 | 0.02 | 0.02 |
| | K₂O | 0.002 | 0.002 | 0.002 | 0.002 | 0.003 | 0.004 | 0.004 | 0.003 |
| | MgO | 1.94 | 1.90 | 1.95 | 1.90 | 1.84 | 1.94 | 1.90 | 1.85 |
| | CaO | 2.69 | 2.62 | 2.70 | 2.62 | 2.55 | 2.68 | 2.63 | 2.56 |
| | SrO | 0.02 | 0.01 | 0.03 | 0.02 | 0.00 | 0.03 | 0.02 | 0.01 |
| | BaO | 0.00 | 0.00 | 0.00 | 0.00 | 0.00 | 0.00 | 0.00 | 0.00 |
| | ZrO₂ | 0.01 | 0.02 | 0.05 | 0.04 | 0.03 | 0.07 | 0.00 | 0.10 |
| | TiO₂ | 0.000 | 0.000 | 0.000 | 0.000 | 0.000 | 0.000 | 0.000 | 0.000 |
| | SnO₂ | 0.20 | 0.20 | 0.20 | 0.20 | 0.21 | 0.22 | 0.19 | 0.21 |
| | Fe₂O₃ | 0.004 | 0.005 | 0.004 | 0.005 | 0.005 | 0.004 | 0.005 | 0.005 |

| | | | | | | | | |
|---|---|---|---|---|---|---|---|---|
| Mg + Ca + Sr + Ba | 4.65 | 4.53 | 4.68 | 4.54 | 4.39 | 4.65 | 4.55 | 4.42 |
| (Mg + Ca + Sr + Ba)/Al | 0.72 | 0.36 | 0.72 | 0.36 | 0.24 | 0.72 | 0.36 | 0.24 |
| B − (Mg + Ca + Sr + Ba) | 20.6 | 20.0 | 16.7 | 16.6 | 16.3 | 13.0 | 12.1 | 12.4 |
| (Mg + Ca + Sr + Ba)/ | 0.049 | 0.048 | 0.049 | 0.048 | 0.046 | 0.049 | 0.048 | 0.046 |
| (Si + Al + B) | | | | | | | | |
| B − Al | 18.7 | 11.8 | 14.9 | 8.4 | 2.2 | 11.1 | 3.8 | −1.8 |
| Li + Na + K | 0.022 | 0.022 | 0.022 | 0.022 | 0.023 | 0.034 | 0.024 | 0.023 |
| (Sr + Ba)/B | 0.001 | 0.000 | 0.001 | 0.001 | 0.000 | 0.002 | 0.001 | 0.001 |
| B/(Sr + Ba) | 1,260 | 2,450 | 713 | 1,055 | ∞ | 587 | 830 | 1,680 |
| (Sr + Ba)/(Mg + Ca) | 0.004 | 0.002 | 0.006 | 0.004 | 0.000 | 0.006 | 0.004 | 0.002 |
| ρ [g/cm³] | 2.18 | 2.23 | 2.20 | 2.24 | 2.29 | 2.21 | 2.26 | 2.30 |
| α(20-200° C.) [×10⁻⁷/° C.] | 32.8 | 31.7 | 30.0 | 28.9 | 29.4 | 27.1 | 26.2 | 26.5 |
| α(20-220° C.) [×10⁻⁷/° C.] | 32.7 | 31.8 | 30.0 | 28.9 | 29.5 | 27.1 | 26.3 | 26.7 |
| α(20-260° C.) [×10⁻⁷/° C.] | 32.5 | 31.8 | 29.8 | 29.0 | 29.8 | 27.0 | 26.4 | 27.0 |
| α(20-300° C.) [×10⁻⁷/° C.] | 32.3 | 31.8 | 29.6 | 29.0 | 30.0 | 26.8 | 26.5 | 27.2 |
| α(30-380° C.) [×10⁻⁷/° C.] | 31.7 | 31.7 | 29.2 | 29.0 | 30.3 | 26.4 | 26.5 | 27.7 |
| α(20-300° C.) − α(20-200° C.) | −0.5 | 0.1 | −0.4 | 0.1 | 0.6 | −0.3 | 0.3 | 0.7 |
| [×10⁻⁷/° C.] | | | | | | | | |
| Ps [° C.] | 551 | 575 | 570 | 604 | 606 | 611 | 635 | 644 |
| Ta [° C.] | 611 | 636 | 644 | 664 | 674 | 696 | 699 | 718 |
| Ts [° C.] | Unmea- | Unmea- | Unmea- | Unmea- | 1,036 | Unmea- | Unmea- | 1,041 |
| | sured | sured | sured | sured | | sured | sured | |
| 10^{4.0} dPa · s [° C.] | 1,303 | 1,233 | 1,356 | 1,279 | 1,242 | 1,421 | 1,335 | 1,270 |
| 10^{3.0} dPa · s [° C.] | 1,499 | 1,405 | 1,556 | 1,457 | 1,376 | 1,622 | 1,518 | 1,428 |
| 10^{2.5} dPa · s [° C.] | 1,620 | 1,513 | 1,680 | 1,569 | 1,476 | 1,756 | 1,634 | 1,529 |
| E [GPa] | 51 | 56 | 54 | 59 | 64 | 57 | 62 | 67 |
| TL [° C.] | 1,060 | Unmea- | 1,068 | Unmea- | Unmea- | 1,074 | 1,216 or | Unmea- |
| | | sured | | sured | sured | | more | sured |
| logηTL [dPa · s] | 5.9 | Unmea- | 6.5 | Unmea- | Unmea- | 7.2 | 5.0 or | Unmea- |
| | | sured | | sured | sured | | less | sured |
| β-OH [mm⁻¹] | Unmea- | 0.27 | 0.46 | 0.27 | 0.17 | 0.43 | 0.26 | 0.20 |
| | sured | | | | | | | |
| Transmittance at 265 nm and | Unmea- | Unmea- | Unmea- | Unmea- | Unmea- | Unmea- | Unmea- | Unmea- |
| thickness of 1 mm [%] | sured | sured | sured | sured | sured | sured | sured | sured |
| Transmittance at 305 nm and | Unmea- | Unmea- | Unmea- | Unmea- | Unmea- | Unmea- | Unmea- | Unmea- |
| thickness of 1 mm [%] | sured | sured | sured | sured | sured | sured | sured | sured |
| Transmittance at 355 nm and | Unmea- | Unmea- | Unmea- | Unmea- | Unmea- | Unmea- | Unmea- | Unmea- |
| thickness of 1 mm [%] | sured | sured | sured | sured | sured | sured | sured | sured |
| Transmittance at 365 nm and | Unmea- | Unmea- | Unmea- | Unmea- | Unmea- | Unmea- | Unmea- | Unmea- |
| thickness of 1 mm [%] | sured | sured | sured | sured | sured | sured | sured | sured |
| Transmittance at 1,100 nm and | Unmea- | Unmea- | Unmea- | Unmea- | Unmea- | Unmea- | Unmea- | Unmea- |
| thickness of 1 mm [%] | sured | sured | sured | sured | sured | sured | sured | sured |
| Specific dielectric constant | 4.09 | 4.30 | 4.13 | 4.33 | 4.54 | 4.17 | 4.36 | 4.56 |
| (25° C., 2.45 GHz) | | | | | | | | |
| Dielectric dissipation factor | 0.00092 | 0.00126 | 0.00098 | 0.00132 | 0.00162 | 0.00109 | 0.00145 | 0.00178 |
| (25° C., 2.45 GHz) | | | | | | | | |
| Specific dielectric constant | Unmea- | Unmea- | Unmea- | Unmea- | Unmea- | Unmea- | Unmea- | Unmea- |
| (25° C., 10 GHz) | sured | sured | sured | sured | sured | sured | sured | sured |
| Dielectric dissipation factor | Unmea- | Unmea- | Unmea- | Unmea- | Unmea- | Unmea- | Unmea- | Unmea- |
| (25° C., 10 GHz) | sured | sured | sured | sured | sured | sured | sured | sured |
| Processing accuracy of through | ∘ | ∘ | ∘ | ∘ | ∘ | ∘ | ∘ | ∘ |
| holes | | | | | | | | |

TABLE 2

| | | No. 9 | No. 10 | No. 11 | No. 12 | No. 13 | No. 14 | No. 15 | No. 16 |
|---|---|---|---|---|---|---|---|---|---|
| Composition | SiO₂ | 63.15 | 57.73 | 66.40 | 61.27 | 55.91 | 70.28 | 65.71 | 59.66 |
| (mass %) | Al₂O₃ | 6.5 | 12.5 | 6.5 | 12.6 | 18.4 | 6.5 | 12.7 | 18.4 |
| | B₂O₃ | 24.9 | 24.5 | 21.7 | 20.9 | 20.6 | 17.9 | 16.3 | 16.8 |
| | Na₂O | 0.02 | 0.02 | 0.02 | 0.02 | 0.02 | 0.02 | 0.02 | 0.02 |
| | K₂O | 0.003 | 0.003 | 0.003 | 0.003 | 0.002 | 0.004 | 0.003 | 0.002 |
| | MgO | 0.65 | 0.63 | 0.65 | 0.63 | 0.60 | 0.65 | 0.62 | 0.61 |
| | CaO | 4.45 | 4.32 | 4.42 | 4.33 | 4.23 | 4.42 | 4.36 | 4.22 |
| | SrO | 0.02 | 0.01 | 0.03 | 0.02 | 0.00 | 0.03 | 0.02 | 0.01 |
| | BaO | 0.00 | 0.00 | 0.00 | 0.00 | 0.00 | 0.00 | 0.00 | 0.00 |
| | ZrO₂ | 0.09 | 0.08 | 0.06 | 0.01 | 0.03 | 0.01 | 0.08 | 0.06 |
| | TiO₂ | 0.000 | 0.000 | 0.000 | 0.001 | 0.000 | 0.000 | 0.000 | 0.000 |
| | SnO₂ | 0.21 | 0.20 | 0.21 | 0.21 | 0.20 | 0.22 | 0.18 | 0.21 |
| | Fe₂O₃ | 0.004 | 0.004 | 0.004 | 0.005 | 0.005 | 0.004 | 0.005 | 0.005 |

| | | | | | | | | |
|---|---|---|---|---|---|---|---|---|
| Mg + Ca + Sr + Ba | 5.12 | 4.96 | 5.10 | 4.98 | 4.83 | 5.10 | 5.00 | 4.84 |
| (Mg + Ca + Sr + Ba)/Al | 0.79 | 0.40 | 0.78 | 0.40 | 0.26 | 0.79 | 0.39 | 0.26 |
| B − (Mg + Ca + Sr + Ba) | 19.8 | 19.5 | 16.6 | 15.9 | 15.8 | 12.8 | 11.3 | 12.0 |
| (Mg + Ca + Sr + Ba)/ | 0.054 | 0.052 | 0.054 | 0.053 | 0.051 | 0.054 | 0.053 | 0.051 |
| (Si + Al + B) | | | | | | | | |
| B − Al | 18.4 | 12.0 | 15.2 | 8.3 | 2.2 | 11.4 | 3.6 | −1.6 |
| Li + Na + K | 0.023 | 0.023 | 0.023 | 0.023 | 0.022 | 0.024 | 0.023 | 0.022 |
| (Sr + Ba)/B | 0.001 | 0.000 | 0.001 | 0.001 | 0.000 | 0.002 | 0.001 | 0.001 |
| B/(Sr + Ba) | 1,245 | 2,450 | 723 | 1,045 | ∞ | 597 | 815 | 1,680 |
| (Sr + Ba)/(Mg + Ca) | 0.004 | 0.002 | 0.006 | 0.004 | 0.000 | 0.006 | 0.004 | 0.002 |
| ρ [g/cm³] | 2.20 | 2.23 | 2.21 | 2.24 | 2.29 | 2.22 | 2.26 | 2.31 |
| α(20-200° C.) [×10⁻⁷/° C.] | 33.1 | 32.3 | 30.7 | 29.4 | 29.3 | 28.2 | 27.1 | 26.9 |
| α(20-220° C.) [×10⁻⁷/° C.] | 33.1 | 32.4 | 30.7 | 29.5 | 29.5 | 28.2 | 27.2 | 27.1 |
| α(20-260° C.) [×10⁻⁷/° C.] | 32.9 | 32.4 | 30.6 | 29.6 | 29.8 | 28.1 | 27.3 | 27.4 |
| α(20-300° C.) [×10⁻⁷/° C.] | 32.7 | 32.4 | 30.4 | 29.7 | 30.0 | 27.9 | 27.4 | 27.6 |
| α(30-380° C.) [×10⁻⁷/° C.] | 32.2 | 32.3 | 29.9 | 29.7 | 30.4 | 27.6 | 27.5 | 28.1 |
| α(20-300° C.) − α(20-200° C.) | −0.4 | 0.1 | −0.4 | 0.3 | 0.7 | −0.3 | 0.3 | 0.8 |
| [×10⁻⁷/° C.] | | | | | | | | |
| Ps [° C.] | 551 | 573 | 576 | 596 | 610 | 618 | 626 | 648 |
| Ta [° C.] | 613 | 629 | 646 | 653 | 669 | 694 | 686 | 712 |
| Ts [° C.] | Unmea- | Unmea- | Unmea- | Unmea- | Unmea- | Unmea- | Unmea- | 1,035 |
| | sured | sured | sured | sured | sured | sured | sured | |
| 10^{4.0} dPa · s [° C.] | 1,288 | 1,238 | 1,346 | 1,281 | 1,238 | 1,415 | 1,344 | 1,282 |
| 10^{3.0} dPa · s [° C.] | 1,487 | 1,412 | 1,548 | 1,459 | 1,374 | 1,615 | 1,529 | 1,438 |
| 10^{2.5} dPa · s [° C.] | 1,611 | 1,523 | 1,672 | 1,570 | 1,477 | 1,731 | 1,642 | 1,543 |
| E [GPa] | 52 | 56 | 55 | 58 | 64 | 57 | 62 | 67 |
| TL [° C.] | 1,017 | 1,196 | 1,053 | 1,214 | Unmea- | 1,010 or | 1,276 | Unmea- |
| | | | | | sured | less | | sured |
| logηTL [dPa · s] | 6.3 | 4.3 | 6.5 | 4.5 | Unmea- | 7.7 or | 4.51 | Unmea- |
| | | | | | sured | more | | sured |
| β-OH [mm⁻¹] | Unmea- | 0.26 | 0.45 | 0.30 | 0.18 | Unmea- | 0.26 | 0.19 |
| | sured | | | | | sured | | |
| Transmittance at 265 nm and | Unmea- | Unmea- | Unmea- | Unmea- | Unmea- | Unmea- | Unmea- | Unmea- |
| thickness of 1 mm [%] | sured | sured | sured | sured | sured | sured | sured | sured |
| Transmittance at 305 nm and | Unmea- | Unmea- | Unmea- | Unmea- | Unmea- | Unmea- | Unmea- | Unmea- |
| thickness of 1 mm [%] | sured | sured | sured | sured | sured | sured | sured | sured |
| Transmittance at 355 nm and | Unmea- | Unmea- | Unmea- | Unmea- | Unmea- | Unmea- | Unmea- | Unmea- |
| thickness of 1 mm [%] | sured | sured | sured | sured | sured | sured | sured | sured |
| Transmittance at 365 nm and | Unmea- | Unmea- | Unmea- | Unmea- | Unmea- | Unmea- | Unmea- | Unmea- |
| thickness of 1 mm [%] | sured | sured | sured | sured | sured | sured | sured | sured |
| Transmittance at 1,100 nm and | Unmea- | Unmea- | Unmea- | Unmea- | Unmea- | Unmea- | Unmea- | Unmea- |
| thickness of 1 mm [%] | sured | sured | sured | sured | sured | sured | sured | sured |
| Specific dielectric constant | 4.17 | 4.36 | 4.20 | 4.38 | 4.59 | 4.20 | 4.39 | 4.63 |
| (25° C., 2.45 GHz) | | | | | | | | |
| Dielectric dissipation factor | 0.00096 | 0.00125 | 0.00105 | 0.00135 | 0.00169 | 0.00112 | 0.0015 | 0.00185 |
| (25° C., 2.45 GHz) | | | | | | | | |
| Specific dielectric constant | Unmea- | Unmea- | Unmea- | Unmea- | Unmea- | Unmea- | Unmea- | Unmea- |
| (25° C., 10 GHz) | sured | sured | sured | sured | sured | sured | sured | sured |
| Dielectric dissipation factor | Unmea- | Unmea- | Unmea- | Unmea- | Unmea- | Unmea- | Unmea- | Unmea- |
| (25° C., 10 GHz) | sured | sured | sured | sured | sured | sured | sured | sured |
| Processing accuracy of through | ∘ | ∘ | ∘ | ∘ | ∘ | ∘ | ∘ | ∘ |
| holes | | | | | | | | |

TABLE 3

| | | No. 17 | No. 18 | No. 19 | No. 20 | No. 21 | No. 22 | No. 23 | No. 24 |
|---|---|---|---|---|---|---|---|---|---|
| Composition | SiO₂ | 63.69 | 59.56 | 67.38 | 61.91 | 56.63 | 71.18 | 65.65 | 60.19 |
| (mass %) | Al₂O₃ | 6.6 | 12.9 | 6.6 | 12.7 | 18.6 | 6.6 | 12.7 | 18.6 |
| | B₂O₃ | 25.3 | 23.1 | 21.6 | 21.0 | 20.5 | 17.8 | 17.2 | 16.9 |
| | Na₂O | 0.02 | 0.01 | 0.01 | 0.02 | 0.01 | 0.01 | 0.01 | 0.01 |
| | K₂O | 0.002 | 0.002 | 0.003 | 0.002 | 0.002 | 0.002 | 0.003 | 0.002 |
| | MgO | 3.25 | 3.24 | 3.26 | 3.19 | 3.11 | 3.27 | 3.19 | 3.11 |
| | CaO | 0.94 | 0.93 | 0.93 | 0.91 | 0.88 | 0.93 | 0.91 | 0.87 |
| | SrO | 0.02 | 0.01 | 0.03 | 0.02 | 0.00 | 0.03 | 0.02 | 0.01 |
| | BaO | 0.00 | 0.00 | 0.00 | 0.00 | 0.00 | 0.00 | 0.00 | 0.00 |
| | ZrO₂ | 0.01 | 0.03 | 0.02 | 0.04 | 0.05 | 0.00 | 0.10 | 0.09 |
| | TiO₂ | 0.000 | 0.000 | 0.000 | 0.000 | 0.000 | 0.000 | 0.000 | 0.000 |
| | SnO₂ | 0.21 | 0.21 | 0.21 | 0.20 | 0.21 | 0.22 | 0.21 | 0.21 |
| | Fe₂O₃ | 0.004 | 0.005 | 0.004 | 0.005 | 0.004 | 0.004 | 0.005 | 0.005 |

| | | | | | | | | |
|---|---|---|---|---|---|---|---|---|
| Mg + Ca + Sr + Ba | 4.21 | 4.18 | 4.22 | 4.12 | 3.99 | 4.23 | 4.12 | 3.99 |
| (Mg + Ca + Sr + Ba)/Al | 0.64 | 0.32 | 0.64 | 0.32 | 0.21 | 0.65 | 0.32 | 0.21 |
| B − (Mg + Ca + Sr + Ba) | 21.1 | 18.9 | 17.4 | 16.9 | 16.5 | 13.6 | 13.1 | 12.9 |
| (Mg + Ca + Sr + Ba)/ | 0.044 | 0.044 | 0.044 | 0.043 | 0.042 | 0.044 | 0.043 | 0.042 |
| (Si + Al + B) | | | | | | | | |
| B − Al | 18.8 | 10.2 | 15.1 | 8.3 | 1.9 | 11.3 | 4.5 | −1.7 |
| Li + Na + K | 0.022 | 0.012 | 0.013 | 0.022 | 0.012 | 0.012 | 0.013 | 0.012 |
| (Sr + Ba)/B | 0.001 | 0.000 | 0.001 | 0.001 | 0.000 | 0.002 | 0.001 | 0.001 |
| B/(Sr + Ba) | 1,265 | 2,310 | 720 | 1,050 | ∞ | 593 | 860 | 1,690 |
| (Sr + Ba)/(Mg + Ca) | 0.005 | 0.002 | 0.007 | 0.005 | 0.000 | 0.007 | 0.005 | 0.003 |
| ρ [g/cm³] | 2.18 | 2.23 | 2.19 | 2.24 | 2.29 | Unmea- | 2.25 | 2.30 |
| | | | | | | sured | | |
| α(20-200° C.) [×10⁻⁷/° C.] | 32.1 | 29.8 | 29.0 | 28.3 | 28.8 | 25.9 | 25.3 | 26.2 |
| α(20-220° C.) [×10⁻⁷/° C.] | 32.0 | 29.8 | 28.9 | 28.3 | 28.9 | 25.9 | 25.4 | 26.3 |
| α(20-260° C.) [×10⁻⁷/° C.] | 31.8 | 29.9 | 28.8 | 28.4 | 29.2 | 25.7 | 25.5 | 26.6 |
| α(20-300° C.) [×10⁻⁷/° C.] | 31.5 | 29.9 | 28.5 | 28.4 | 29.3 | 25.6 | 25.5 | 26.8 |
| α(30-380° C.) [×10⁻⁷/° C.] | 30.9 | 29.8 | 28.0 | 28.3 | 29.6 | 25.1 | 25.5 | 27.2 |
| α(20-300° C.) − α(20-200° C.) | −0.6 | 0.1 | −0.5 | 0.1 | 0.5 | −0.4 | 0.2 | 0.6 |
| [×10⁻⁷/° C.] | | | | | | | | |
| Ps [° C.] | 560 | 577 | 572 | 589 | Unmea- | 604 | 631 | 647 |
| | | | | | surable | | | |
| Ta [° C.] | 618 | 646 | 648 | 664 | Unmea- | 695 | 721 | 731 |
| | | | | | surable | | | |
| Ts [° C.] | Unmea- | Unmea- | Unmea- | Unmea- | Unmea- | Unmea- | Unmea- | 1,127 |
| | sured | sured | sured | sured | surable | sured | sured | |
| 10^{4.0} dPa · s [° C.] | 1,309 | 1,255 | 1,373 | 1,282 | 1,238 | 1,430 | 1,334 | 1,283 |
| 10^{3.0} dPa · s [° C.] | 1,498 | 1,424 | 1,572 | 1,456 | 1,373 | 1,626 | 1,512 | 1,428 |
| 10^{2.5} dPa · s [° C.] | 1,616 | 1,531 | 1,695 | 1,565 | 1,468 | 1,737 | 1,621 | 1,527 |
| E [GPa] | 51 | 57 | 54 | 59 | 64 | Unmea- | 62 | 68 |
| | | | | | | sured | | |
| TL [° C.] | 1,140 | 1,265 | 1,145 | 1,269 | Unmea- | 1,140 | Unmea- | Unmea- |
| | | | | | sured | | sured | sured |
| logηTL [dPa · s] | 5.3 | 3.9 | 5.8 | 4.1 | Unmea- | 6.6 | Unmea- | Unmea- |
| | | | | | sured | | sured | sured |
| β-OH [mm⁻¹] | Unmea- | 0.26 | 0.43 | 0.29 | 0.15 | Unmea- | 0.28 | 0.16 |
| | sured | | | | | sured | | |
| Transmittance at 265 nm and | Unmea- | Unmea- | Unmea- | Unmea- | Unmea- | Unmea- | Unmea- | Unmea- |
| thickness of 1 mm [%] | sured | sured | sured | sured | sured | sured | sured | sured |
| Transmittance at 305 nm and | Unmea- | Unmea- | Unmea- | Unmea- | Unmea- | Unmea- | Unmea- | Unmea- |
| thickness of 1 mm [%] | sured | sured | sured | sured | sured | sured | sured | sured |
| Transmittance at 355 nm and | Unmea- | Unmea- | Unmea- | Unmea- | Unmea- | Unmea- | Unmea- | Unmea- |
| thickness of 1 mm [%] | sured | sured | sured | sured | sured | sured | sured | sured |
| Transmittance at 365 nm and | Unmea- | Unmea- | Unmea- | Unmea- | Unmea- | Unmea- | Unmea- | Unmea- |
| thickness of 1 mm [%] | sured | sured | sured | sured | sured | sured | sured | sured |
| Transmittance at 1,100 nm and | Unmea- | Unmea- | Unmea- | Unmea- | Unmea- | Unmea- | Unmea- | Unmea- |
| thickness of 1 mm [%] | sured | sured | sured | sured | sured | sured | sured | sured |
| Specific dielectric constant | 4.04 | 4.27 | 4.05 | 4.27 | 4.48 | 4.09 | 4.29 | 4.50 |
| (25° C., 2.45 GHz) | | | | | | | | |
| Dielectric dissipation factor | 0.00095 | 0.00133 | 0.00097 | 0.00134 | 0.00164 | 0.00103 | 0.00139 | 0.00175 |
| (25° C., 2.45 GHz) | | | | | | | | |
| Specific dielectric constant | Unmea- | Unmea- | Unmea- | Unmea- | Unmea- | Unmea- | Unmea- | Unmea- |
| (25° C., 10 GHz) | sured | sured | sured | sured | sured | sured | sured | sured |
| Dielectric dissipation factor | Unmea- | Unmea- | Unmea- | Unmea- | Unmea- | Unmea- | Unmea- | Unmea- |
| (25° C., 10 GHz) | sured | sured | sured | sured | sured | sured | sured | sured |
| Processing accuracy of through | ∘ | ∘ | ∘ | ∘ | ∘ | ∘ | ∘ | ∘ |
| holes | | | | | | | | |

TABLE 4

| | | No. 25 | No. 26 | No. 27 | No. 28 | No. 29 | No. 30 | No. 31 | No. 32 |
|---|---|---|---|---|---|---|---|---|---|
| Composition | SiO₂ | 62.39 | 56.93 | 65.93 | 60.46 | 55.28 | 69.62 | 64.29 | 59.06 |
| (mass %) | Al₂O₃ | 9.6 | 15.4 | 9.6 | 15.5 | 21.1 | 9.6 | 15.6 | 21.2 |
| | B₂O₃ | 24.7 | 24.4 | 21.1 | 20.8 | 20.5 | 17.5 | 16.9 | 16.6 |
| | Na₂O | 0.02 | 0.02 | 0.02 | 0.02 | 0.02 | 0.02 | 0.02 | 0.02 |
| | K₂O | 0.003 | 0.002 | 0.002 | 0.002 | 0.002 | 0.003 | 0.002 | 0.002 |
| | MgO | 1.28 | 1.24 | 1.28 | 1.24 | 1.19 | 1.27 | 1.24 | 1.21 |
| | CaO | 1.77 | 1.72 | 1.77 | 1.72 | 1.67 | 1.76 | 1.72 | 1.68 |
| | SrO | 0.001 | 0.008 | 0.007 | 0.009 | 0.003 | 0.002 | 0.002 | 0.005 |
| | BaO | 0.00 | 0.00 | 0.00 | 0.00 | 0.00 | 0.00 | 0.00 | 0.00 |
| | ZrO₂ | 0.04 | 0.07 | 0.08 | 0.03 | 0.02 | 0.01 | 0.02 | 0.02 |
| | TiO₂ | 0.000 | 0.000 | 0.000 | 0.002 | 0.000 | 0.000 | 0.000 | 0.000 |
| | SnO₂ | 0.19 | 0.21 | 0.21 | 0.21 | 0.21 | 0.21 | 0.20 | 0.20 |
| | Fe₂O₃ | 0.004 | 0.004 | 0.004 | 0.004 | 0.005 | 0.004 | 0.005 | 0.005 |

| | | | | | | | | |
|---|---|---|---|---|---|---|---|---|
| Mg + Ca + Sr + Ba | 3.05 | 2.97 | 3.06 | 2.97 | 2.86 | 3.03 | 2.96 | 2.90 |
| (Mg + Ca + Sr + Ba)/Al | 0.32 | 0.19 | 0.32 | 0.19 | 0.14 | 0.32 | 0.19 | 0.14 |
| B − (Mg + Ca + Sr + Ba) | 21.6 | 21.4 | 18.0 | 17.8 | 17.6 | 14.5 | 13.9 | 13.7 |
| (Mg + Ca + Sr + Ba)/ | 0.032 | 0.031 | 0.032 | 0.031 | 0.030 | 0.031 | 0.031 | 0.030 |
| (Si + Al + B) | | | | | | | | |
| B − Al | 15.1 | 9.0 | 11.5 | 5.3 | −0.6 | 7.9 | 1.3 | −4.6 |
| Li + Na + K | 0.023 | 0.022 | 0.022 | 0.022 | 0.022 | 0.023 | 0.022 | 0.022 |
| (Sr + Ba)/B | 0.000 | 0.000 | 0.000 | 0.000 | 0.000 | 0.000 | 0.000 | 0.000 |
| B/(Sr + Ba) | 24,700 | 3,050 | 3,014 | 2,311 | 6,833 | 8,750 | 8,450 | 3,320 |
| (Sr + Ba)/(Mg + Ca) | 0.000 | 0.003 | 0.002 | 0.003 | 0.001 | 0.001 | 0.001 | 0.002 |
| ρ [g/cm³] | 2.19 | 2.24 | 2.20 | 2.25 | 2.30 | 2.21 | 2.27 | 2.32 |
| α(20-200° C.) [×10⁻⁷/° C.] | 30.9 | 30.8 | 27.9 | 28.0 | 29.8 | 24.9 | 25.5 | 26.6 |
| α(20-220° C.) [×10⁻⁷/° C.] | 30.8 | 30.8 | 27.9 | 28.0 | 29.9 | 24.9 | 25.5 | 26.8 |
| α(20-260° C.) [×10⁻⁷/° C.] | 30.7 | 30.9 | 27.7 | 28.1 | 30.2 | 24.8 | 25.7 | 27.1 |
| α(20-300° C.) [×10⁻⁷/° C.] | 30.5 | 30.9 | 27.5 | 28.1 | 30.3 | 24.6 | 25.7 | 27.3 |
| α(30-380° C.) [×10⁻⁷/° C.] | 30.0 | 30.8 | 27.1 | 28.1 | 30.6 | 24.3 | 25.8 | 27.7 |
| α(20-300° C.) − α(20-200° C.) | −0.4 | 0.1 | −0.4 | 0.2 | 0.5 | −0.2 | 0.2 | 0.7 |
| [×10⁻⁷/° C.] | | | | | | | | |
| Ps [° C.] | 545 | Unmea- | 584 | 585 | Unmea- | 608 | Unmea- | Unmea- |
| | | surable | | | surable | | surable | surable |
| Ta [° C.] | 614 | Unmea- | 657 | 660 | Unmea- | 692 | Unmea- | Unmea- |
| | | surable | | | surable | | surable | surable |
| Ts [° C.] | Unmea- | Unmea- | Unmea- | Unmea- | Unmea- | Unmea- | Unmea- | Unmea- |
| | sured | surable | sured | sured | surable | sured | surable | surable |
| 10^{4.0} dPa · s [° C.] | 1,292 | 1,252 | 1,352 | 1,278 | Unmea- | 1,417 | 1,327 | Unmea- |
| | | | | | surable | | | surable |
| 10^{3.0} dPa · s [° C.] | 1,481 | 1,390 | 1,544 | 1,444 | Unmea- | 1,615 | 1,495 | Unmea- |
| | | | | | surable | | | surable |
| 10^{2.5} dPa · s [° C.] | 1,597 | 1,496 | 1,659 | 1,551 | Unmea- | 1,736 | 1,603 | Unmea- |
| | | | | | surable | | | surable |
| E [GPa] | 51 | 57 | 55 | 60 | 66 | 58 | 64 | 69 |
| TL [° C.] | 1,252 | Unmea- | 1,270 | Unmea- | Unmea- | Unmea- | Unmea- | Unmea- |
| | | sured | | sured | sured | sured | sured | sured |
| logηTL [dPa · s] | 4.3 | Unmea- | 4.6 | Unmea- | Unmea- | Unmea- | Unmea- | Unmea- |
| | | sured | | sured | sured | sured | sured | sured |
| β-OH [mm⁻¹] | 0.37 | 0.22 | 0.32 | 0.23 | 0.14 | 0.39 | 0.23 | 0.15 |
| Transmittance at 265 nm and | Unmea- | Unmea- | Unmea- | Unmea- | Unmea- | Unmea- | Unmea- | Unmea- |
| thickness of 1 mm [%] | sured | sured | sured | sured | sured | sured | sured | sured |
| Transmittance at 305 nm and | Unmea- | Unmea- | Unmea- | Unmea- | Unmea- | Unmea- | Unmea- | Unmea- |
| thickness of 1 mm [%] | sured | sured | sured | sured | sured | sured | sured | sured |
| Transmittance at 355 nm and | Unmea- | Unmea- | Unmea- | Unmea- | Unmea- | Unmea- | Unmea- | Unmea- |
| thickness of 1 mm [%] | sured | sured | sured | sured | sured | sured | sured | sured |
| Transmittance at 365 nm and | Unmea- | Unmea- | Unmea- | Unmea- | Unmea- | Unmea- | Unmea- | Unmea- |
| thickness of 1 mm [%] | sured | sured | sured | sured | sured | sured | sured | sured |
| Transmittance at 1,100 nm and | Unmea- | Unmea- | Unmea- | Unmea- | Unmea- | Unmea- | Unmea- | Unmea- |
| thickness of 1 mm [%] | sured | sured | sured | sured | sured | sured | sured | sured |
| Specific dielectric constant | 4.10 | 4.30 | 4.11 | 4.31 | 4.52 | 4.13 | 4.34 | 4.56 |
| (25° C., 2.45 GHz) | | | | | | | | |
| Dielectric dissipation factor | 0.00087 | 0.00116 | 0.00094 | 0.00122 | 0.00147 | 0.00102 | 0.00129 | 0.00161 |
| (25° C., 2.45 GHz) | | | | | | | | |
| Specific dielectric constant | Unmea- | Unmea- | Unmea- | Unmea- | Unmea- | Unmea- | Unmea- | Unmea- |
| (25° C., 10 GHz) | sured | sured | sured | sured | sured | sured | sured | sured |
| Dielectric dissipation factor | Unmea- | Unmea- | Unmea- | Unmea- | Unmea- | Unmea- | Unmea- | Unmea- |
| (25° C., 10 GHz) | sured | sured | sured | sured | sured | sured | sured | sured |
| Processing accuracy of through | ∘ | ∘ | ∘ | ∘ | ∘ | ∘ | ∘ | ∘ |
| holes | | | | | | | | |

TABLE 5

| | | No. 33 | No. 34 | No. 35 | No. 36 | No. 37 | No. 38 | No. 39 | No. 40 |
|---|---|---|---|---|---|---|---|---|---|
| Composition | SiO₂ | 62.00 | 56.92 | 64.08 | 61.94 | 55.56 | 69.50 | 64.42 | 59.01 |
| (mass %) | Al₂O₃ | 9.5 | 15.4 | 11.4 | 13.7 | 21.1 | 9.6 | 15.6 | 21.2 |
| | B₂O₃ | 25.0 | 24.2 | 21.0 | 20.9 | 20.0 | 17.4 | 16.5 | 16.4 |
| | Na₂O | 0.02 | 0.02 | 0.02 | 0.02 | 0.02 | 0.02 | 0.02 | 0.02 |
| | K₂O | 0.002 | 0.002 | 0.002 | 0.002 | 0.002 | 0.002 | 0.003 | 0.002 |
| | MgO | 0.62 | 0.62 | 0.63 | 0.62 | 0.60 | 0.63 | 0.61 | 0.60 |
| | CaO | 2.63 | 2.58 | 2.61 | 2.59 | 2.51 | 2.63 | 2.59 | 2.51 |
| | SrO | 0.006 | 0.004 | 0.007 | 0.009 | 0.003 | 0.003 | 0.003 | 0.050 |
| | BaO | 0.00 | 0.00 | 0.00 | 0.00 | 0.00 | 0.00 | 0.00 | 0.00 |
| | ZrO₂ | 0.02 | 0.04 | 0.05 | 0.00 | 0.00 | 0.00 | 0.05 | 0.00 |
| | TiO₂ | 0.000 | 0.000 | 0.000 | 0.000 | 0.000 | 0.000 | 0.000 | 0.000 |
| | SnO₂ | 0.20 | 0.21 | 0.20 | 0.21 | 0.20 | 0.21 | 0.20 | 0.20 |
| | Fe₂O₃ | 0.004 | 0.004 | 0.004 | 0.004 | 0.005 | 0.004 | 0.005 | 0.005 |

| | | | | | | | | |
|---|---|---|---|---|---|---|---|---|
| Mg + Ca + Sr + Ba | 3.26 | 3.20 | 3.25 | 3.22 | 3.11 | 3.26 | 3.20 | 3.16 |
| (Mg + Ca + Sr + Ba)/Al | 0.34 | 0.21 | 0.28 | 0.23 | 0.15 | 0.34 | 0.21 | 0.15 |
| B − (Mg + Ca + Sr + Ba) | 21.7 | 21.0 | 17.8 | 17.7 | 16.9 | 14.1 | 13.3 | 13.2 |
| (Mg + Ca + Sr + Ba)/ | 0.034 | 0.033 | 0.034 | 0.033 | 0.032 | 0.034 | 0.033 | 0.033 |
| (Si + Al + B) | | | | | | | | |
| B − Al | 15.5 | 8.8 | 9.6 | 7.2 | −1.1 | 7.8 | 0.9 | −4.8 |
| Li + Na + K | 0.022 | 0.022 | 0.022 | 0.022 | 0.022 | 0.022 | 0.023 | 0.022 |
| (Sr + Ba)/B | 0.000 | 0.000 | 0.000 | 0.000 | 0.000 | 0.000 | 0.000 | 0.003 |
| B/(Sr + Ba) | 4,167 | 6,050 | 3,000 | 2,322 | 6,667 | 5,800 | 5,500 | 328 |
| (Sr + Ba)/(Mg + Ca) | 0.002 | 0.001 | 0.002 | 0.003 | 0.001 | 0.001 | 0.001 | 0.016 |
| ρ [g/cm³] | 2.19 | 2.24 | 2.22 | 2.24 | 2.31 | 2.22 | 2.27 | 2.32 |
| α(20-200° C.) [×10⁻⁷/° C.] | 31.2 | 30.8 | 27.9 | 28.1 | 29.0 | 25.2 | 25.4 | 26.3 |
| α(20-220° C.) [×10⁻⁷/° C.] | 31.2 | 30.8 | 28.9 | 28.1 | 29.1 | 25.2 | 25.5 | 26.5 |
| α(20-260° C.) [×10⁻⁷/° C.] | 31.0 | 30.9 | 27.8 | 28.2 | 29.3 | 25.2 | 25.6 | 26.8 |
| α(20-300° C.) [×10⁻⁷/° C.] | 30.8 | 30.9 | 27.7 | 28.1 | 29.5 | 25.0 | 25.7 | 27.0 |
| α(30-380° C.) [×10⁻⁷/° C.] | 30.3 | 30.8 | 27.5 | 28.0 | 29.8 | 24.7 | 25.7 | 27.4 |
| α(20-300° C.) − α(20-200° C.) | −0.4 | 0.1 | −0.1 | 0.0 | 0.5 | −0.2 | 0.3 | 0.7 |
| [×10⁻⁷/° C.] | | | | | | | | |
| Ps [° C.] | 547 | 560 | 575 | 584 | Unmea- | 606 | 631 | Unmea- |
| | | | | | surable | | | surable |
| Ta [° C.] | 614 | 625 | 645 | 655 | Unmea- | 677 | 709 | Unmea- |
| | | | | | surable | | | surable |
| Ts [° C.] | Unmea- | Unmea- | 993 | 1,004 | Unmea- | 1,012 | Unmea- | Unmea- |
| | sured | sured | | | surable | | sured | surable |
| 10^{4.0} dPa · s [° C.] | 1,295 | 1,239 | 1,324 | 1,293 | Unmea- | 1,411 | 1,327 | 1,375 |
| | | | | | surable | | | |
| 10^{3.0} dPa · s [° C.] | 1,485 | 1,389 | 1,510 | 1,471 | Unmea- | 1,609 | 1,500 | 1,450 |
| | | | | | surable | | | |
| 10^{2.5} dPa · s [° C.] | 1,602 | 1,493 | 1,624 | 1,581 | Unmea- | 1,731 | 1,610 | 1,524 |
| | | | | | surable | | | |
| E [GPa] | 52 | 57 | 56 | 58 | 66 | 58 | 63 | 69 |
| TL [° C.] | 1,260 | Unmea- | 1,324 | Unmea- | Unmea- | 1,281 | Unmea- | Unmea- |
| | | sured | | sured | sured | | sured | sured |
| logηTL [dPa · s] | 4.3 | Unmea- | 4.0 | Unmea- | Unmea- | 4.9 | Unmea- | Unmea- |
| | | sured | | sured | sured | | sured | sured |
| β-OH [mm⁻¹] | Unmea- | 0.20 | 0.35 | Unmea- | 0.15 | 0.45 | 0.28 | 0.19 |
| | sured | | | sured | | | | |
| Transmittance at 265 nm and | Unmea- | Unmea- | Unmea- | Unmea- | Unmea- | Unmea- | Unmea- | Unmea- |
| thickness of 1 mm [%] | sured | sured | sured | sured | sured | sured | sured | sured |
| Transmittance at 305 nm and | Unmea- | Unmea- | Unmea- | Unmea- | Unmea- | Unmea- | Unmea- | Unmea- |
| thickness of 1 mm [%] | sured | sured | sured | sured | sured | sured | sured | sured |
| Transmittance at 355 nm and | Unmea- | Unmea- | Unmea- | Unmea- | Unmea- | Unmea- | Unmea- | Unmea- |
| thickness of 1 mm [%] | sured | sured | sured | sured | sured | sured | sured | sured |
| Transmittance at 365 nm and | Unmea- | Unmea- | Unmea- | Unmea- | Unmea- | Unmea- | Unmea- | Unmea- |
| thickness of 1 mm [%] | sured | sured | sured | sured | sured | sured | sured | sured |
| Transmittance at 1,100 nm and | Unmea- | Unmea- | Unmea- | Unmea- | Unmea- | Unmea- | Unmea- | Unmea- |
| thickness of 1 mm [%] | sured | sured | sured | sured | sured | sured | sured | sured |
| Specific dielectric constant | 4.12 | 4.31 | 4.20 | 4.29 | 4.55 | 4.16 | 4.37 | 4.57 |
| (25° C., 2.45 GHz) | | | | | | | | |
| Dielectric dissipation factor | 0.00087 | 0.00113 | 0.00100 | 0.00114 | 0.00145 | 0.00099 | 0.00134 | 0.00163 |
| (25° C., 2.45 GHz) | | | | | | | | |
| Specific dielectric constant | Unmea- | Unmea- | Unmea- | Unmea- | Unmea- | Unmea- | Unmea- | Unmea- |
| (25° C., 10 GHz) | sured | sured | sured | sured | sured | sured | sured | sured |
| Dielectric dissipation factor | Unmea- | Unmea- | Unmea- | Unmea- | Unmea- | Unmea- | Unmea- | Unmea- |
| (25° C., 10 GHz) | sured | sured | sured | sured | sured | sured | sured | sured |
| Processing accuracy of through | ∘ | ∘ | ∘ | ∘ | ∘ | ∘ | ∘ | ∘ |
| holes | | | | | | | | |

TABLE 6

| | | No. 41 | No. 42 | No. 43 | No. 44 | No. 45 | No. 46 | No. 47 | No. 48 |
|---|---|---|---|---|---|---|---|---|---|
| Composition | SiO₂ | 62.74 | 57.28 | 66.02 | 60.71 | 54.92 | 69.73 | 64.48 | 59.03 |
| (mass %) | Al₂O₃ | 9.6 | 15.5 | 9.6 | 15.6 | 21.0 | 9.6 | 15.6 | 21.2 |
| | B₂O₃ | 24.6 | 24.2 | 21.3 | 20.7 | 21.2 | 17.6 | 16.9 | 16.8 |
| | Na₂O | 0.02 | 0.02 | 0.02 | 0.02 | 0.02 | 0.02 | 0.02 | 0.01 |
| | K₂O | 0.002 | 0.002 | 0.002 | 0.002 | 0.003 | 0.002 | 0.002 | 0.002 |
| | MgO | 1.92 | 1.86 | 1.92 | 1.86 | 1.80 | 1.92 | 1.87 | 1.82 |
| | CaO | 0.91 | 0.89 | 0.91 | 0.88 | 0.84 | 0.90 | 0.88 | 0.86 |
| | SrO | 0.003 | 0.030 | 0.003 | 0.010 | 0.003 | 0.003 | 0.006 | 0.004 |
| | BaO | 0.00 | 0.00 | 0.00 | 0.00 | 0.00 | 0.00 | 0.00 | 0.00 |
| | ZrO₂ | 0.00 | 0.00 | 0.01 | 0.01 | 0.01 | 0.01 | 0.03 | 0.06 |
| | TiO₂ | 0.000 | 0.000 | 0.000 | 0.000 | 0.000 | 0.000 | 0.000 | 0.000 |
| | SnO₂ | 0.20 | 0.21 | 0.21 | 0.21 | 0.20 | 0.21 | 0.20 | 0.21 |
| | Fe₂O₃ | 0.000 | 0.003 | 0.002 | 0.001 | 0.004 | 0.007 | 0.010 | 0.008 |

| | | | | | | | | |
|---|---|---|---|---|---|---|---|---|
| Mg + Ca + Sr + Ba | 2.83 | 2.78 | 2.83 | 2.75 | 2.64 | 2.82 | 2.76 | 2.68 |
| (Mg + Ca + Sr + Ba)/Al | 0.30 | 0.18 | 0.30 | 0.18 | 0.13 | 0.29 | 0.18 | 0.13 |
| B − (Mg + Ca + Sr + Ba) | 21.8 | 21.4 | 18.5 | 18.0 | 18.6 | 14.8 | 14.1 | 14.1 |
| (Mg + Ca + Sr + Ba)/ | 0.029 | 0.029 | 0.029 | 0.028 | 0.027 | 0.029 | 0.028 | 0.028 |
| (Si + Al + B) | | | | | | | | |
| B − Al | 15.0 | 8.7 | 11.7 | 5.1 | 0.2 | 8.0 | 1.3 | −4.4 |
| Li + Na + K | 0.022 | 0.022 | 0.022 | 0.022 | 0.023 | 0.022 | 0.022 | 0.012 |
| (Sr + Ba)/B | 0.000 | 0.001 | 0.000 | 0.000 | 0.000 | 0.000 | 0.000 | 0.000 |
| B/(Sr + Ba) | 8,200 | 807 | 7,100 | 2,070 | 7,067 | 5,867 | 2,817 | 4,200 |
| (Sr + Ba)/(Mg + Ca) | 0.001 | 0.011 | 0.001 | 0.004 | 0.001 | 0.001 | 0.002 | 0.001 |
| ρ [g/cm³] | 2.18 | 2.24 | 2.20 | 2.25 | Unmea- | 2.21 | 2.26 | 2.32 |
| | | | | | sured | | | |
| α(20-200° C.) [×10⁻⁷/° C.] | 30.7 | 30.6 | 27.5 | 27.8 | Unmea- | 24.6 | 25.1 | 27.4 |
| | | | | | sured | | | |
| α(20-220° C.) [×10⁻⁷/° C.] | 30.6 | 30.7 | 27.4 | 27.9 | Unmea- | 24.6 | 25.2 | 27.6 |
| | | | | | sured | | | |
| α(20-260° C.) [×10⁻⁷/° C.] | 30.4 | 30.7 | 27.3 | 28.0 | Unmea- | 24.5 | 25.3 | 27.8 |
| | | | | | sured | | | |
| α(20-300° C.) [×10⁻⁷/° C.] | 30.2 | 30.7 | 27.1 | 27.9 | Unmea- | 24.4 | 25.4 | 28.0 |
| | | | | | sured | | | |
| α(30-380° C.) [×10⁻⁷/° C.] | 29.7 | 30.5 | 26.6 | 27.9 | Unmea- | 24.1 | 25.4 | 28.3 |
| | | | | | sured | | | |
| α(20-300° C.) − α(20-200° C.) | −0.5 | 0.0 | −0.4 | 0.1 | Unmea- | −0.2 | 0.2 | 0.6 |
| [×10⁻⁷/° C.] | | | | | sured | | | |
| Ps [° C.] | 540 | Unmea- | 568 | 586 | Unmea- | 597 | Unmea- | 636 |
| | | surable | | | sured | | surable | |
| Ta [° C.] | 609 | Unmea- | 646 | 666 | Unmea- | 684 | Unmea- | 722 |
| | | surable | | | sured | | surable | |
| Ts [° C.] | Unmea- | Unmea- | 1,032 | Unmea- | Unmea- | 1,065 | Unmea- | Unmea- |
| | sured | surable | | sured | sured | | surable | sured |
| 10^{4.0} dPa · s [° C.] | 1,291 | 1,244 | 1,354 | 1,276 | Unmea- | 1,404 | 1,323 | 1,242 |
| | | | | | sured | | | |
| 10^{3.0} dPa · s [° C.] | 1,477 | 1,389 | 1,548 | 1,442 | Unmea- | 1,596 | 1,497 | 1,411 |
| | | | | | sured | | | |
| 10^{2.5} dPa · s [° C.] | 1,593 | 1,489 | 1,672 | 1,548 | Unmea- | 1,713 | 1,606 | 1,512 |
| | | | | | sured | | | |
| E [GPa] | 52 | 57 | 55 | 60 | Unmea- | 58 | 64 | 70 |
| | | | | | sured | | | |
| TL [° C.] | 1,270 | Unmea- | 1,335 | Unmea- | Unmea- | 1,312 | Unmea- | Unmea- |
| | | sured | | sured | sured | | sured | sured |
| logηTL [dPa · s] | 4.2 | Unmea- | 4.2 | Unmea- | Unmea- | 4.8 | Unmea- | Unmea- |
| | | sured | | sured | sured | | sured | sured |
| β-OH [mm⁻¹] | 0.38 | 0.20 | 0.36 | 0.24 | Unmea- | 0.43 | 0.22 | 0.18 |
| | | | | | sured | | | |
| Transmittance at 265 nm and | Unmea- | Unmea- | Unmea- | Unmea- | Unmea- | Unmea- | Unmea- | Unmea- |
| thickness of 1 mm [%] | sured | sured | sured | sured | sured | sured | sured | sured |
| Transmittance at 305 nm and | Unmea- | Unmea- | Unmea- | Unmea- | Unmea- | Unmea- | Unmea- | Unmea- |
| thickness of 1 mm [%] | sured | sured | sured | sured | sured | sured | sured | sured |
| Transmittance at 355 nm and | Unmea- | Unmea- | Unmea- | Unmea- | Unmea- | Unmea- | Unmea- | Unmea- |
| thickness of 1 mm [%] | sured | sured | sured | sured | sured | sured | sured | sured |
| Transmittance at 365 nm and | Unmea- | Unmea- | Unmea- | Unmea- | Unmea- | Unmea- | Unmea- | Unmea- |
| thickness of 1 mm [%] | sured | sured | sured | sured | sured | sured | sured | sured |
| Transmittance at 1,100 nm and | Unmea- | Unmea- | Unmea- | Unmea- | Unmea- | Unmea- | Unmea- | Unmea- |
| thickness of 1 mm [%] | sured | sured | sured | sured | sured | sured | sured | sured |
| Specific dielectric constant | 4.04 | 4.26 | 4.09 | 4.28 | Unmea- | 4.10 | 4.30 | 4.50 |
| (25° C., 2.45 GHz) | | | | | sured | | | |
| Dielectric dissipation factor | 0.00086 | 0.00112 | 0.00091 | 0.00120 | Unmea- | 0.00095 | 0.00124 | 0.00146 |
| (25° C., 2.45 GHz) | | | | | sured | | | |
| Specific dielectric constant | Unmea- | Unmea- | Unmea- | Unmea- | Unmea- | Unmea- | Unmea- | Unmea- |
| (25° C., 10 GHz) | sured | sured | sured | sured | sured | sured | sured | sured |
| Dielectric dissipation factor | Unmea- | Unmea- | Unmea- | Unmea- | Unmea- | Unmea- | Unmea- | Unmea- |
| (25° C., 10 GHz) | sured | sured | sured | sured | sured | sured | sured | sured |
| Processing accuracy of through | ∘ | ∘ | ∘ | ∘ | ∘ | ∘ | ∘ | ∘ |
| holes | | | | | | | | |

TABLE 7

| | | No. 49 | No. 50 | No. 51 | No. 52 | No. 53 | No. 54 | No. 55 | No. 56 |
|---|---|---|---|---|---|---|---|---|---|
| Composition | SiO₂ | 62.11 | 54.33 | 63.22 | 62.49 | 63.89 | 60.01 | 61.01 | 62.30 |
| (mass %) | Al₂O₃ | 4.8 | 4.7 | 4.8 | 3.2 | 3.2 | 7.9 | 7.9 | 7.9 |
| | B₂O₃ | 29.6 | 37.5 | 28.5 | 30.8 | 29.4 | 26.9 | 25.9 | 24.6 |
| | Na₂O | 0.02 | 0.03 | 0.01 | 0.02 | 0.02 | 0.01 | 0.00 | 0.02 |
| | K₂O | 0.007 | 0.007 | 0.005 | 0.006 | 0.007 | 0.004 | 0.004 | 0.005 |
| | MgO | 0.63 | 0.63 | 0.63 | 0.64 | 0.64 | 0.63 | 0.63 | 0.63 |
| | CaO | 2.64 | 2.61 | 2.62 | 2.65 | 2.63 | 4.32 | 4.34 | 4.33 |
| | SrO | 0.000 | 0.000 | 0.000 | 0.000 | 0.000 | 0.000 | 0.000 | 0.000 |
| | BaO | 0.00 | 0.00 | 0.00 | 0.00 | 0.00 | 0.00 | 0.00 | 0.00 |
| | ZrO₂ | 0.00 | 0.00 | 0.00 | 0.00 | 0.00 | 0.00 | 0.00 | 0.00 |
| | TiO₂ | 0.000 | 0.000 | 0.000 | 0.000 | 0.000 | 0.000 | 0.000 | 0.000 |
| | SnO₂ | 0.19 | 0.19 | 0.21 | 0.19 | 0.21 | 0.19 | 0.21 | 0.21 |
| | Fe₂O₃ | 0.003 | 0.003 | 0.003 | 0.003 | 0.004 | 0.034 | 0.004 | 0.004 |

| | | | | | | | | |
|---|---|---|---|---|---|---|---|---|
| Mg + Ca + Sr + Ba | 3.27 | 3.24 | 3.25 | 3.29 | 3.27 | 4.95 | 4.97 | 4.96 |
| (Mg + Ca + Sr + Ba)/Al | 0.68 | 0.69 | 0.68 | 1.03 | 1.02 | 0.63 | 0.63 | 0.63 |
| B − (Mg + Ca + Sr + Ba) | 26.3 | 34.3 | 25.3 | 27.5 | 26.1 | 22.0 | 20.9 | 19.6 |
| (Mg + Ca + Sr + Ba)/ | 0.034 | 0.034 | 0.034 | 0.034 | 0.034 | 0.052 | 0.052 | 0.052 |
| (Si + Al + B) | | | | | | | | |
| B − Al | 24.8 | 32.8 | 23.7 | 27.6 | 26.2 | 19.0 | 18.0 | 16.7 |
| Li + Na + K | 0.027 | 0.037 | 0.015 | 0.026 | 0.027 | 0.014 | 0.004 | 0.025 |
| (Sr + Ba)/B | 0.000 | 0.000 | 0.000 | 0.000 | 0.000 | 0.000 | 0.000 | 0.000 |
| B/(Sr + Ba) | ∞ | ∞ | ∞ | ∞ | ∞ | ∞ | ∞ | ∞ |
| (Sr + Ba)/(Mg + Ca) | 0.000 | 0.000 | 0.000 | 0.000 | 0.000 | 0.000 | 0.000 | 0.000 |
| ρ [g/cm³] | 2.14 | 2.12 | 2.15 | 2.13 | 2.13 | 2.20 | 2.20 | 2.21 |
| α(20-200° C.) [×10⁻⁷/° C.] | 35.1 | 41.4 | 33.4 | 36.1 | 34.7 | 33.6 | 32.8 | 32.1 |
| α(20-220° C.) [×10⁻⁷/° C.] | 34.9 | 41.2 | 33.3 | 35.9 | 34.6 | 33.5 | 32.8 | 32.1 |
| α(20-260° C.) [×10⁻⁷/° C.] | 34.6 | 40.9 | 33.0 | 35.5 | 34.2 | 33.4 | 32.7 | 32.0 |
| α(20-300° C.) [×10⁻⁷/° C.] | 34.3 | 40.5 | 32.6 | 35.1 | 33.8 | 33.3 | 32.5 | 31.9 |
| α(30-380° C.) [×10⁻⁷/° C.] | 33.6 | 40.0 | 31.8 | 34.2 | 33.0 | 32.9 | 32.1 | 31.5 |
| α(20-300° C.) − α(20-200° C.) | −0.8 | −0.8 | −0.8 | −1.0 | −0.9 | −0.3 | −0.3 | −0.2 |
| [×10⁻⁷/° C.] | | | | | | | | |
| Ps [° C.] | 505 | 487 | 510 | 515 | 519 | 550 | 556 | 561 |
| Ta [° C.] | 564 | 539 | 574 | 569 | 575 | 609 | 616 | 622 |
| Ts [° C.] | Unmea- | Unmea- | Unmea- | Unmea- | Unmea- | Unmea- | Unmea- | Unmea- |
| | sured | sured | sured | sured | sured | sured | sured | sured |
| 10^{4.0} dPa · s [° C.] | 1,314 | 1,201 | 1,344 | 1,306 | 1,340 | 1,277 | 1,284 | 1,296 |
| 10^{3.0} dPa · s [° C.] | 1,519 | 1,404 | 1,552 | 1,525 | 1,556 | 1,469 | 1,477 | 1,489 |
| 10^{2.5} dPa · s [° C.] | 1,645 | 1,529 | 1,690 | 1,660 | 1,690 | 1,588 | 1,596 | 1,610 |
| E [GPa] | 46 | 42 | 47 | 45 | 46 | 52 | 53 | 53 |
| TL [° C.] | 975 | Unmea- | 981 | 1,194 | 1,161 | 939 | 952 | 938 |
| | | sured | | | | | | |
| logηTL [dPa · s] | 6.6 | Unmea- | 6.8 | 4.7 | 5.1 | 7.1 | 7.0 | 7.3 |
| | | sured | | | | | | |
| β-OH [mm⁻¹] | Unmea- | Unmea- | Unmea- | Unmea- | 1.07 | 0.70 | 0.84 | 0.79 |
| | sured | sured | sured | sured | | | | |
| Transmittance at 265 nm and | Unmea- | Unmea- | Unmea- | Unmea- | Unmea- | Unmea- | Unmea- | Unmea- |
| thickness of 1 mm [%] | sured | sured | sured | sured | sured | sured | sured | sured |
| Transmittance at 305 nm and | Unmea- | Unmea- | Unmea- | Unmea- | Unmea- | Unmea- | Unmea- | Unmea- |
| thickness of 1 mm [%] | sured | sured | sured | sured | sured | sured | sured | sured |
| Transmittance at 355 nm and | Unmea- | Unmea- | Unmea- | Unmea- | Unmea- | Unmea- | Unmea- | Unmea- |
| thickness of 1 mm [%] | sured | sured | sured | sured | sured | sured | sured | sured |
| Transmittance at 365 nm and | Unmea- | Unmea- | Unmea- | Unmea- | Unmea- | Unmea- | Unmea- | Unmea- |
| thickness of 1 mm [%] | sured | sured | sured | sured | sured | sured | sured | sured |
| Transmittance at 1,100 nm and | Unmea- | Unmea- | Unmea- | Unmea- | Unmea- | Unmea- | Unmea- | Unmea- |
| thickness of 1 mm [%] | sured | sured | sured | sured | sured | sured | sured | sured |
| Specific dielectric constant | 3.94 | 3.89 | 3.96 | 3.91 | 4.06 | 4.20 | 4.21 | 4.21 |
| (25° C., 2.45 GHz) | | | | | | | | |
| Dielectric dissipation factor | 0.00066 | 0.00067 | 0.00069 | 0.00064 | 0.00066 | 0.00100 | 0.00100 | 0.00101 |
| (25° C., 2.45 GHz) | | | | | | | | |
| Specific dielectric constant | Unmea- | Unmea- | Unmea- | Unmea- | Unmea- | Unmea- | Unmea- | Unmea- |
| (25° C., 10 GHz) | sured | sured | sured | sured | sured | sured | sured | sured |
| Dielectric dissipation factor | Unmea- | Unmea- | Unmea- | Unmea- | Unmea- | Unmea- | Unmea- | Unmea- |
| (25° C., 10 GHz) | sured | sured | sured | sured | sured | sured | sured | sured |
| Processing accuracy of through | ∘ | ∘ | ∘ | ∘ | ∘ | ∘ | ∘ | ∘ |
| holes | | | | | | | | |

TABLE 8

| | | No. 57 | No. 58 | No. 59 | No. 60 | No. 61 | No. 62 | No. 63 | No. 64 |
|---|---|---|---|---|---|---|---|---|---|
| Composition | SiO₂ | 61.33 | 62.12 | 62.00 | 62.22 | 62.27 | 61.34 | 62.52 | 61.83 |
| (mass %) | Al₂O₃ | 6.3 | 3.2 | 4.8 | 6.4 | 4.8 | 7.9 | 7.9 | 8.0 |
| | B₂O₃ | 28.9 | 31.6 | 30.1 | 28.3 | 29.6 | 27.3 | 26.1 | 27.1 |
| | Na₂O | 0.01 | 0.02 | 0.02 | 0.02 | 0.02 | 0.02 | 0.02 | 0.03 |
| | K₂O | 0.005 | 0.006 | 0.007 | 0.007 | 0.006 | 0.007 | 0.008 | 0.007 |
| | MgO | 0.63 | 1.92 | 1.93 | 1.94 | 1.29 | 0.63 | 0.64 | 1.91 |
| | CaO | 2.61 | 0.91 | 0.90 | 0.90 | 1.78 | 2.60 | 2.62 | 0.90 |
| | SrO | 0.000 | 0.000 | 0.000 | 0.000 | 0.000 | 0.000 | 0.000 | 0.000 |
| | BaO | 0.00 | 0.00 | 0.00 | 0.00 | 0.00 | 0.00 | 0.00 | 0.00 |
| | ZrO₂ | 0.00 | 0.00 | 0.00 | 0.00 | 0.00 | 0.00 | 0.00 | 0.00 |
| | TiO₂ | 0.000 | 0.003 | 0.000 | 0.004 | 0.000 | 0.000 | 0.000 | 0.005 |
| | SnO₂ | 0.21 | 0.21 | 0.21 | 0.21 | 0.21 | 0.20 | 0.19 | 0.21 |
| | Fe₂O₃ | 0.003 | 0.013 | 0.033 | 0.003 | 0.024 | 0.004 | 0.004 | 0.004 |

| | | | | | | | | |
|---|---|---|---|---|---|---|---|---|
| Mg + Ca + Sr + Ba | 3.24 | 2.83 | 2.83 | 2.84 | 3.07 | 3.23 | 3.26 | 2.81 |
| (Mg + Ca + Sr + Ba)/Al | 0.51 | 0.88 | 0.59 | 0.44 | 0.64 | 0.41 | 0.41 | 0.35 |
| B − (Mg + Ca + Sr + Ba) | 25.7 | 28.8 | 27.3 | 25.5 | 26.5 | 24.1 | 22.8 | 24.3 |
| (Mg + Ca + Sr + Ba)/ | 0.034 | 0.029 | 0.029 | 0.029 | 0.032 | 0.033 | 0.034 | 0.029 |
| (Si + Al + B) | | | | | | | | |
| B − Al | 22.6 | 28.4 | 25.3 | 21.9 | 24.8 | 19.4 | 18.2 | 19.1 |
| Li + Na + K | 0.015 | 0.026 | 0.027 | 0.027 | 0.026 | 0.027 | 0.028 | 0.037 |
| (Sr + Ba)/B | 0.000 | 0.000 | 0.000 | 0.000 | 0.000 | 0.000 | 0.000 | 0.000 |
| B/(Sr + Ba) | ∞ | ∞ | ∞ | ∞ | ∞ | ∞ | ∞ | ∞ |
| (Sr + Ba)/(Mg + Ca) | 0.000 | 0.000 | 0.000 | 0.000 | 0.000 | 0.000 | 0.000 | 0.000 |
| ρ [g/cm³] | 2.16 | 2.12 | 2.14 | 2.15 | 2.14 | 2.17 | 2.17 | 2.17 |
| α(20-200° C.) [×10⁻⁷/° C.] | 33.5 | 36.2 | 34.6 | 33.4 | 34.6 | 32.6 | 31.7 | 31.9 |
| α(20-220° C.) [×10⁻⁷/° C.] | 33.4 | 36.0 | 34.4 | 33.2 | 34.5 | 32.5 | 31.6 | 31.8 |
| α(20-260° C.) [×10⁻⁷/° C.] | 33.1 | 35.7 | 34.1 | 33.0 | 34.2 | 32.3 | 31.4 | 31.6 |
| α(20-300° C.) [×10⁻⁷/° C.] | 32.8 | 35.2 | 33.7 | 32.6 | 33.8 | 32.0 | 31.2 | 31.3 |
| α(30-380° C.) [×10⁻⁷/° C.] | 32.1 | 34.5 | 32.9 | 31.8 | 33.0 | 31.3 | 30.7 | 30.7 |
| α(20-300° C.) − α(20-200° C.) | −0.7 | −1.0 | −0.9 | −0.8 | −0.9 | −0.6 | −0.5 | −0.6 |
| [×10⁻⁷/° C.] | | | | | | | | |
| Ps [° C.] | 510 | 515 | 522 | 532 | 514 | 530 | 537 | 544 |
| Ta [° C.] | 573 | 571 | 579 | 590 | 572 | 591 | 599 | 604 |
| Ts [° C.] | Unmea- | Unmea- | Unmea- | Unmea- | Unmea- | Unmea- | Unmea- | Unmea- |
| | sured | sured | sured | sured | sured | sured | sured | sured |
| 10^{4.0} dPa · s [° C.] | 1,307 | 1,332 | 1,332 | 1,315 | 1,333 | 1,307 | 1,319 | 1,305 |
| 10^{3.0} dPa · s [° C.] | 1,509 | 1,544 | 1,537 | 1,511 | 1,541 | 1,504 | 1,516 | 1,498 |
| 10^{2.5} dPa · s [° C.] | 1,634 | 1,682 | 1,667 | 1,634 | 1,678 | 1,627 | 1,636 | 1,621 |
| E [GPa] | 48 | 44 | 46 | 47 | 46 | 49 | 50 | 49 |
| TL [° C.] | 924 | Unmea- | 1,119 | 1,143 | 1,028 | 1,154 | 1,157 | 1,215 |
| | | sured | | | | | | |
| logηTL [dPa · s] | 7.2 | Unmea- | 5.4 | 5.2 | 6.2 | 5.1 | 5.2 | 4.6 |
| | | sured | | | | | | |
| β-OH [mm⁻¹] | 0.55 | 0.95 | 0.70 | 0.60 | 0.67 | 0.41 | 0.43 | 0.44 |
| Transmittance at 265 nm and | Unmea- | Unmea- | Unmea- | Unmea- | Unmea- | Unmea- | Unmea- | Unmea- |
| thickness of 1 mm [%] | sured | sured | sured | sured | sured | sured | sured | sured |
| Transmittance at 305 nm and | Unmea- | Unmea- | Unmea- | Unmea- | Unmea- | Unmea- | Unmea- | Unmea- |
| thickness of 1 mm [%] | sured | sured | sured | sured | sured | sured | sured | sured |
| Transmittance at 355 nm and | Unmea- | Unmea- | Unmea- | Unmea- | Unmea- | Unmea- | Unmea- | Unmea- |
| thickness of 1 mm [%] | sured | sured | sured | sured | sured | sured | sured | sured |
| Transmittance at 365 nm and | Unmea- | Unmea- | Unmea- | Unmea- | Unmea- | Unmea- | Unmea- | Unmea- |
| thickness of 1 mm [%] | sured | sured | sured | sured | sured | sured | sured | sured |
| Transmittance at 1,100 nm and | Unmea- | Unmea- | Unmea- | Unmea- | Unmea- | Unmea- | Unmea- | Unmea- |
| thickness of 1 mm [%] | sured | sured | sured | sured | sured | sured | sured | sured |
| Specific dielectric constant | 4.00 | 3.85 | 3.90 | 3.96 | 3.93 | 4.06 | 4.06 | 4.00 |
| (25° C., 2.45 GHz) | | | | | | | | |
| Dielectric dissipation factor | 0.00070 | 0.00066 | 0.00068 | 0.00074 | 0.00066 | 0.00082 | 0.00084 | 0.00085 |
| (25° C., 2.45 GHz) | | | | | | | | |
| Specific dielectric constant | 3.98 | Unmea- | Unmea- | Unmea- | Unmea- | Unmea- | Unmea- | Unmea- |
| (25° C., 10 GHz) | | sured | sured | sured | sured | sured | sured | sured |
| Dielectric dissipation factor | 0.00120 | Unmea- | Unmea- | Unmea- | Unmea- | Unmea- | Unmea- | Unmea- |
| (25° C., 10 GHz) | | sured | sured | sured | sured | sured | sured | sured |
| Processing accuracy of through | ∘ | ∘ | ∘ | ∘ | ∘ | ∘ | ∘ | ∘ |
| holes | | | | | | | | |

TABLE 9

| | | No. 65 | No. 66 | No. 67 | No. 68 | No. 69 | No. 70 | No. 71 | No. 72 |
|---|---|---|---|---|---|---|---|---|---|
| Composition | SiO₂ | 62.75 | 61.55 | 61.54 | 61.81 | 61.99 | 61.62 | 61.43 | 58.68 |
| (mass %) | Al₂O₃ | 8.0 | 7.5 | 7.1 | 7.5 | 7.1 | 7.1 | 7.1 | 7.0 |
| | B₂O₃ | 26.2 | 27.1 | 27.1 | 27.1 | 27.0 | 27.6 | 27.6 | 26.1 |
| | Na₂O | 0.02 | 0.00 | 0.00 | 0.00 | 0.00 | 0.00 | 0.00 | 0.00 |
| | K₂O | 0.008 | 0.000 | 0.000 | 0.000 | 0.000 | 0.000 | 0.000 | 0.000 |
| | MgO | 1.91 | 0.63 | 0.63 | 0.63 | 0.63 | 0.63 | 0.63 | 0.62 |
| | CaO | 0.90 | 2.61 | 2.61 | 2.35 | 2.18 | 2.44 | 2.62 | 2.57 |
| | SrO | 0.000 | 0.480 | 0.810 | 0.480 | 0.800 | 0.320 | 0.320 | 4.750 |
| | BaO | 0.00 | 0.00 | 0.00 | 0.00 | 0.00 | 0.00 | 0.00 | 0.01 |
| | ZrO₂ | 0.00 | 0.00 | 0.00 | 0.00 | 0.00 | 0.00 | 0.00 | 0.00 |
| | TiO₂ | 0.000 | 0.000 | 0.000 | 0.000 | 0.000 | 0.000 | 0.000 | 0.000 |
| | SnO₂ | 0.21 | 0.23 | 0.23 | 0.23 | 0.23 | 0.23 | 0.23 | 0.23 |
| | Fe₂O₃ | 0.004 | 0.004 | 0.004 | 0.004 | 0.004 | 0.004 | 0.004 | 0.034 |

| | | | | | | | | |
|---|---|---|---|---|---|---|---|---|
| Mg + Ca + Sr + Ba | 2.81 | 3.72 | 4.05 | 3.46 | 3.61 | 3.39 | 3.57 | 7.95 |
| (Mg + Ca + Sr + Ba)/Al | 0.35 | 0.50 | 0.57 | 0.46 | 0.51 | 0.47 | 0.50 | 1.13 |
| B − (Mg + Ca + Sr + Ba) | 23.4 | 23.3 | 23.0 | 23.6 | 23.4 | 24.2 | 24.1 | 18.1 |
| (Mg + Ca + Sr + Ba)/ | 0.029 | 0.039 | 0.042 | 0.036 | 0.038 | 0.035 | 0.037 | 0.087 |
| (Si + Al + B) | | | | | | | | |
| B − Al | 18.2 | 19.6 | 19.9 | 19.6 | 19.9 | 20.5 | 20.5 | 19.1 |
| Li + Na + K | 0.028 | 0.000 | 0.000 | 0.000 | 0.000 | 0.000 | 0.000 | 0.000 |
| (Sr + Ba)/B | 0.000 | 0.018 | 0.030 | 0.018 | 0.030 | 0.012 | 0.012 | 0.182 |
| B/(Sr + Ba) | ∞ | 56 | 33 | 56 | 34 | 86 | 86 | 5 |
| (Sr + Ba)/(Mg + Ca) | 0.000 | 0.148 | 0.250 | 0.161 | 0.285 | 0.104 | 0.098 | 1.492 |
| ρ [g/cm³] | 2.17 | Unmea- | Unmea- | Unmea- | Unmea- | Unmea- | Unmea- | Unmea- |
| | | sured | sured | sured | sured | sured | sured | sured |
| α(20-200° C.) [×10⁻⁷/° C.] | 31.0 | Unmea- | Unmea- | Unmea- | Unmea- | Unmea- | Unmea- | Unmea- |
| | | sured | sured | sured | sured | sured | sured | sured |
| α(20-220° C.) [×10⁻⁷/° C.] | 30.9 | Unmea- | Unmea- | Unmea- | Unmea- | Unmea- | Unmea- | Unmea- |
| | | sured | sured | sured | sured | sured | sured | sured |
| α(20-260° C.) [×10⁻⁷/° C.] | 30.7 | Unmea- | Unmea- | Unmea- | Unmea- | Unmea- | Unmea- | Unmea- |
| | | sured | sured | sured | sured | sured | sured | sured |
| α(20-300° C.) [×10⁻⁷/° C.] | 30.4 | Unmea- | Unmea- | Unmea- | Unmea- | Unmea- | Unmea- | Unmea- |
| | | sured | sured | sured | sured | sured | sured | sured |
| α(30-380° C.) [×10⁻⁷/° C.] | 29.9 | Unmea- | Unmea- | Unmea- | Unmea- | Unmea- | Unmea- | Unmea- |
| | | sured | sured | sured | sured | sured | sured | sured |
| α(20-300° C.) − α(20-200° C.) | −0.6 | Unmea- | Unmea- | Unmea- | Unmea- | Unmea- | Unmea- | Unmea- |
| [×10⁻⁷/° C.] | | sured | sured | sured | sured | sured | sured | sured |
| Ps [° C.] | 547 | Unmea- | Unmea- | Unmea- | Unmea- | Unmea- | Unmea- | Unmea- |
| | | sured | sured | sured | sured | sured | sured | sured |
| Ta [° C.] | 609 | Unmea- | Unmea- | Unmea- | Unmea- | Unmea- | Unmea- | Unmea- |
| | | sured | sured | sured | sured | sured | sured | sured |
| Ts [° C.] | Unmea- | Unmea- | Unmea- | Unmea- | Unmea- | Unmea- | Unmea- | Unmea- |
| | sured | sured | sured | sured | sured | sured | sured | sured |
| 10^{4.0} dPa · s [° C.] | 1,314 | Unmea- | Unmea- | Unmea- | Unmea- | Unmea- | Unmea- | Unmea- |
| | | sured | sured | sured | sured | sured | sured | sured |
| 10^{3.0} dPa · s [° C.] | 1,508 | Unmea- | Unmea- | Unmea- | Unmea- | Unmea- | Unmea- | Unmea- |
| | | sured | sured | sured | sured | sured | sured | sured |
| 10^{2.5} dPa · s [° C.] | 1,628 | Unmea- | Unmea- | Unmea- | Unmea- | Unmea- | Unmea- | Unmea- |
| | | sured | sured | sured | sured | sured | sured | sured |
| E [GPa] | 50 | Unmea- | Unmea- | Unmea- | Unmea- | Unmea- | Unmea- | Unmea- |
| | | sured | sured | sured | sured | sured | sured | sured |
| TL [° C.] | Unmea- | Unmea- | Unmea- | Unmea- | Unmea- | Unmea- | Unmea- | Unmea- |
| | sured | sured | sured | sured | sured | sured | sured | sured |
| logηTL [dPa · s] | Unmea- | Unmea- | Unmea- | Unmea- | Unmea- | Unmea- | Unmea- | Unmea- |
| | sured | sured | sured | sured | sured | sured | sured | sured |
| β-OH [mm⁻¹] | 0.43 | Unmea- | Unmea- | Unmea- | Unmea- | Unmea- | Unmea- | Unmea- |
| | | sured | sured | sured | sured | sured | sured | sured |
| Transmittance at 265 nm and | Unmea- | Unmea- | Unmea- | Unmea- | Unmea- | Unmea- | Unmea- | Unmea- |
| thickness of 1 mm [%] | sured | sured | sured | sured | sured | sured | sured | sured |
| Transmittance at 305 nm and | Unmea- | Unmea- | Unmea- | Unmea- | Unmea- | Unmea- | Unmea- | Unmea- |
| thickness of 1 mm [%] | sured | sured | sured | sured | sured | sured | sured | sured |
| Transmittance at 355 nm and | Unmea- | Unmea- | Unmea- | Unmea- | Unmea- | Unmea- | Unmea- | Unmea- |
| thickness of 1 mm [%] | sured | sured | sured | sured | sured | sured | sured | sured |
| Transmittance at 365 nm and | Unmea- | Unmea- | Unmea- | Unmea- | Unmea- | Unmea- | Unmea- | Unmea- |
| thickness of 1 mm [%] | sured | sured | sured | sured | sured | sured | sured | sured |
| Transmittance at 1,100 nm and | Unmea- | Unmea- | Unmea- | Unmea- | Unmea- | Unmea- | Unmea- | Unmea- |
| thickness of 1 mm [%] | sured | sured | sured | sured | sured | sured | sured | sured |
| Specific dielectric constant | 4.01 | Unmea- | Unmea- | Unmea- | Unmea- | Unmea- | Unmea- | Unmea- |
| (25° C., 2.45 GHz) | | sured | sured | sured | sured | sured | sured | sured |
| Dielectric dissipation factor | 0.00081 | Unmea- | Unmea- | Unmea- | Unmea- | Unmea- | Unmea- | Unmea- |
| (25° C., 2.45 GHz) | | sured | sured | sured | sured | sured | sured | sured |
| Specific dielectric constant | Unmea- | Unmea- | Unmea- | Unmea- | Unmea- | Unmea- | Unmea- | Unmea- |
| (25° C., 10 GHz) | sured | sured | sured | sured | sured | sured | sured | sured |
| Dielectric dissipation factor | Unmea- | Unmea- | Unmea- | Unmea- | Unmea- | Unmea- | Unmea- | Unmea- |
| (25° C., 10 GHz) | sured | sured | sured | sured | sured | sured | sured | sured |
| Processing accuracy of through | ∘ | Unmea- | Unmea- | Unmea- | Unmea- | Unmea- | Unmea- | Unmea- |
| holes | | sured | sured | sured | sured | sured | sured | sured |

TABLE 10

| | | No. 73 | No. 74 | No. 75 | No. 76 | No. 77 | No. 78 | No. 79 | No. 80 |
|---|---|---|---|---|---|---|---|---|---|
| Composition | SiO₂ | 62.00 | 61.99 | 61.90 | 62.25 | 61.86 | 61.38 | 59.32 | 60.48 |
| (mass %) | Al₂O₃ | 7.5 | 7.2 | 7.5 | 7.2 | 7.2 | 7.2 | 7.3 | 7.2 |
| | B₂O₃ | 26.7 | 26.8 | 27.0 | 26.9 | 27.4 | 27.7 | 27.4 | 27.1 |
| | Na₂O | 0.01 | 0.01 | 0.02 | 0.02 | 0.01 | 0.01 | 0.00 | 0.00 |
| | K₂O | 0.003 | 0.002 | 0.002 | 0.002 | 0.003 | 0.002 | 0.003 | 0.002 |
| | MgO | 0.64 | 0.64 | 0.64 | 0.64 | 0.64 | 0.64 | 0.65 | 0.64 |
| | CaO | 2.69 | 2.71 | 2.45 | 2.28 | 2.52 | 2.70 | 2.70 | 2.71 |
| | SrO | 0.250 | 0.420 | 0.250 | 0.410 | 0.160 | 0.160 | 2.370 | 1.600 |
| | BaO | 0.00 | 0.00 | 0.00 | 0.00 | 0.00 | 0.00 | 0.02 | 0.01 |
| | ZrO₂ | 0.00 | 0.01 | 0.00 | 0.08 | 0.00 | 0.00 | 0.03 | 0.02 |
| | TiO₂ | 0.000 | 0.000 | 0.000 | 0.000 | 0.000 | 0.000 | 0.001 | 0.000 |
| | SnO₂ | 0.20 | 0.20 | 0.20 | 0.21 | 0.20 | 0.20 | 0.20 | 0.20 |
| | Fe₂O₃ | 0.004 | 0.014 | 0.033 | 0.004 | 0.004 | 0.004 | 0.004 | 0.034 |

| | | | | | | | | |
|---|---|---|---|---|---|---|---|---|
| Mg + Ca + Sr + Ba | 3.58 | 3.77 | 3.34 | 3.33 | 3.32 | 3.50 | 5.74 | 4.96 |
| (Mg + Ca + Sr + Ba)/Al | 0.48 | 0.52 | 0.45 | 0.46 | 0.46 | 0.49 | 0.79 | 0.69 |
| B − (Mg + Ca + Sr + Ba) | 23.1 | 23.0 | 23.7 | 23.6 | 24.1 | 24.2 | 21.7 | 22.1 |
| (Mg + Ca + Sr + Ba)/ | 0.037 | 0.039 | 0.035 | 0.035 | 0.034 | 0.036 | 0.061 | 0.052 |
| (Si + Al + B) | | | | | | | | |
| B − Al | 19.2 | 19.6 | 19.5 | 19.7 | 20.2 | 20.5 | 20.1 | 19.9 |
| Li + Na + K | 0.013 | 0.012 | 0.022 | 0.022 | 0.013 | 0.012 | 0.003 | 0.002 |
| (Sr + Ba)/B | 0.009 | 0.016 | 0.009 | 0.015 | 0.006 | 0.006 | 0.087 | 0.059 |
| B/(Sr + Ba) | 107 | 64 | 108 | 66 | 171 | 173 | 11 | 17 |
| (Sr + Ba)/(Mg + Ca) | 0.075 | 0.125 | 0.081 | 0.140 | 0.051 | 0.048 | 0.713 | 0.481 |
| ρ [g/cm³] | 2.17 | 2.17 | 2.17 | 2.17 | 2.16 | 2.17 | 2.21 | 2.20 |
| α(20-200° C.) [×10⁻⁷/° C.] | 32.4 | 32.7 | 32.2 | 32.5 | 32.9 | 33.1 | 33.6 | 33.2 |
| α(20-220° C.) [×10⁻⁷/° C.] | 32.3 | 32.6 | 32.1 | 32.4 | 32.8 | 33.0 | 33.5 | 33.2 |
| α(20-260° C.) [×10⁻⁷/° C.] | 32.1 | 32.4 | 31.9 | 32.2 | 32.5 | 32.7 | 33.4 | 33.0 |
| α(20-300° C.) [×10⁻⁷/° C.] | 31.9 | 32.1 | 31.7 | 31.9 | 32.2 | 32.5 | 33.2 | 32.8 |
| α(30-380° C.) [×10⁻⁷/° C.] | 31.3 | 31.5 | 31.0 | 31.2 | 31.6 | 31.9 | 32.8 | 32.3 |
| α(20-300° C.) − α(20-200° C.) | −0.5 | −0.6 | −0.6 | −0.7 | −0.6 | −0.6 | −0.4 | −0.5 |
| [×10⁻⁷/° C.] | | | | | | | | |
| Ps [° C.] | 532 | 529 | 525 | 522 | 522 | 523 | 544 | 543 |
| Ta [° C.] | 594 | 591 | 589 | 585 | 585 | 585 | 603 | 603 |
| Ts [° C.] | Unmea- | Unmea- | Unmea- | Unmea- | Unmea- | Unmea- | Unmea- | Unmea- |
| | sured | sured | sured | sured | sured | sured | sured | sured |
| 10^{4.0} dPa · s [° C.] | 1,313 | 1,324 | 1,325 | 1,329 | 1,314 | 1,321 | 1,297 | 1,306 |
| 10^{3.0} dPa · s [° C.] | 1,513 | 1,525 | 1,525 | 1,530 | 1,511 | 1,521 | 1,499 | 1,503 |
| 10^{2.5} dPa · s [° C.] | 1,634 | 1,647 | 1,648 | 1,660 | 1,635 | 1,644 | 1,619 | 1,627 |
| E [GPa] | 49 | 49 | 49 | 49 | 48 | 49 | 51 | 50 |
| TL [° C.] | 1,122 | 1,060 | 1,143 | 1,169 | 1,142 | 1,119 | 911 | 924 |
| logηTL [dPa · s] | 5.4 | 6.0 | 5.3 | 5.1 | 5.2 | 5.5 | 7.4 | 7.4 |
| β-OH [mm⁻¹] | 0.50 | 0.48 | 0.53 | 0.58 | 0.50 | 0.44 | 0.44 | 0.48 |
| Transmittance at 265 nm and | Unmea- | Unmea- | Unmea- | Unmea- | Unmea- | Unmea- | Unmea- | Unmea- |
| thickness of 1 mm [%] | sured | sured | sured | sured | sured | sured | sured | sured |
| Transmittance at 305 nm and | Unmea- | Unmea- | Unmea- | Unmea- | Unmea- | Unmea- | Unmea- | Unmea- |
| thickness of 1 mm [%] | sured | sured | sured | sured | sured | sured | sured | sured |
| Transmittance at 355 nm and | Unmea- | Unmea- | Unmea- | Unmea- | Unmea- | Unmea- | Unmea- | Unmea- |
| thickness of 1 mm [%] | sured | sured | sured | sured | sured | sured | sured | sured |
| Transmittance at 365 nm and | Unmea- | Unmea- | Unmea- | Unmea- | Unmea- | Unmea- | Unmea- | Unmea- |
| thickness of 1 mm [%] | sured | sured | sured | sured | sured | sured | sured | sured |
| Transmittance at 1,100 nm and | Unmea- | Unmea- | Unmea- | Unmea- | Unmea- | Unmea- | Unmea- | Unmea- |
| thickness of 1 mm [%] | sured | sured | sured | sured | sured | sured | sured | sured |
| Specific dielectric constant | 4.06 | 4.06 | 4.03 | 4.06 | 4.02 | 4.04 | 4.19 | 4.11 |
| (25° C., 2.45 GHz) | | | | | | | | |
| Dielectric dissipation factor | 0.00083 | 0.00077 | 0.00074 | 0.00074 | 0.00074 | 0.00079 | 0.00093 | 0.00088 |
| (25° C., 2.45 GHz) | | | | | | | | |
| Specific dielectric constant | Unmea- | Unmea- | Unmea- | Unmea- | Unmea- | Unmea- | Unmea- | Unmea- |
| (25° C., 10 GHz) | sured | sured | sured | sured | sured | sured | sured | sured |
| Dielectric dissipation factor | Unmea- | Unmea- | Unmea- | Unmea- | Unmea- | Unmea- | Unmea- | Unmea- |
| (25° C., 10 GHz) | sured | sured | sured | sured | sured | sured | sured | sured |
| Processing accuracy of through | ∘ | ∘ | ∘ | ∘ | ∘ | ∘ | ∘ | ∘ |
| holes | | | | | | | | |

TABLE 11

| | | No. 81 | No. 82 | No. 83 | No. 84 | No. 85 | No. 86 | No. 87 | No. 88 |
|---|---|---|---|---|---|---|---|---|---|
| Composition | SiO₂ | 61.87 | 63.17 | 61.39 | 65.45 | 61.45 | 66.05 | 60.54 | 60.90 |
| (mass %) | Al₂O₃ | 7.0 | 8.1 | 10.3 | 12.6 | 13.3 | 9.7 | 7.2 | 7.3 |
| | B₂O₃ | 27.0 | 23.4 | 25.1 | 17.3 | 21.2 | 21.1 | 27.1 | 23.2 |
| | Na₂O | 0.04 | 0.04 | 0.05 | 0.05 | 0.08 | 0.07 | 0.00 | 0.06 |
| | K₂O | 0.008 | 0.010 | 0.008 | 0.009 | 0.006 | 0.006 | 0.000 | 0.005 |
| | MgO | 0.47 | 0.66 | 0.32 | 0.63 | 0.46 | 1.95 | 0.64 | 0.67 |
| | CaO | 3.59 | 4.43 | 2.63 | 3.96 | 3.50 | 0.90 | 2.71 | 2.66 |
| | SrO | 0.000 | 0.000 | 0.000 | 0.000 | 0.000 | 0.000 | 1.600 | 4.950 |
| | BaO | 0.00 | 0.00 | 0.00 | 0.00 | 0.00 | 0.00 | 0.01 | 0.05 |
| | ZrO₂ | 0.001 | 0.00 | 0.00 | 0.00 | 0.00 | 0.00 | 0.00 | 0.00 |
| | TiO₂ | 0.000 | 0.000 | 0.000 | 0.000 | 0.000 | 0.000 | 0.000 | 0.010 |
| | SnO₂ | 0.02 | 0.18 | 0.20 | 0.00 | 0.00 | 0.22 | 0.20 | 0.19 |
| | Fe₂O₃ | 0.004 | 0.006 | 0.004 | 0.005 | 0.006 | 0.005 | 0.004 | 0.005 |

| | | | | | | | | |
|---|---|---|---|---|---|---|---|---|
| Mg + Ca + Sr + Ba | 4.06 | 5.09 | 2.95 | 4.59 | 3.96 | 2.85 | 4.96 | 8.33 |
| (Mg + Ca + Sr + Ba)/Al | 0.58 | 0.63 | 0.29 | 0.36 | 0.30 | 0.29 | 0.69 | 1.14 |
| B − (Mg + Ca + Sr + Ba) | 22.9 | 18.3 | 22.2 | 12.7 | 17.2 | 18.3 | 22.1 | 14.9 |
| (Mg + Ca + Sr + Ba)/ | 0.042 | 0.054 | 0.030 | 0.048 | 0.041 | 0.029 | 0.052 | 0.091 |
| (Si + Al + B) | | | | | | | | |
| B − Al | 20.0 | 15.3 | 14.8 | 4.7 | 7.9 | 11.4 | 19.9 | 15.9 |
| Li + Na + K | 0.048 | 0.050 | 0.058 | 0.059 | 0.086 | 0.076 | 0.000 | 0.065 |
| (Sr + Ba)/B | 0.000 | 0.000 | 0.000 | 0.000 | 0.000 | 0.000 | 0.059 | 0.216 |
| B/(Sr + Ba) | ∞ | ∞ | ∞ | ∞ | ∞ | ∞ | 17 | 5 |
| (Sr + Ba)/(Mg + Ca) | 0.000 | 0.000 | 0.000 | 0.000 | 0.000 | 0.000 | 0.481 | 1.502 |
| ρ [g/cm³] | 2.18 | 2.22 | 2.19 | 2.25 | 2.44 | 2.20 | Unmea- | 2.28 |
| | | | | | | | sured | |
| α(20-200° C.) [×10⁻⁷/° C.] | 33.3 | 31.4 | 30.4 | 26.2 | 28.7 | 26.9 | Unmea- | 34.1 |
| | | | | | | | sured | |
| α(20-220° C.) [×10⁻⁷/° C.] | 33.2 | 31.4 | 30.4 | 26.2 | 28.8 | 26.8 | Unmea- | 34.1 |
| | | | | | | | sured | |
| α(20-260° C.) [×10⁻⁷/° C.] | 33.0 | 31.3 | 30.3 | 26.2 | 28.8 | 26.8 | Unmea- | 34.0 |
| | | | | | | | sured | |
| α(20-300° C.) [×10⁻⁷/° C.] | 32.7 | 31.2 | 30.1 | 25.9 | 28.7 | 26.6 | Unmea- | 33.9 |
| | | | | | | | sured | |
| α(30-380° C.) [×10⁻⁷/° C.] | 32.1 | 30.9 | 29.6 | 25.9 | 28.7 | 26.2 | Unmea- | 33.7 |
| | | | | | | | sured | |
| α(20-300° C.) − α(20-200° C.) | −0.5 | −0.2 | −0.3 | −0.3 | 0.0 | −0.3 | Unmea- | −0.2 |
| [×10⁻⁷/° C.] | | | | | | | sured | |
| Ps [° C.] | 539 | 582 | 557 | 624 | 598 | 589 | Unmea- | 583 |
| | | | | | | | sured | |
| Ta [° C.] | 599 | 642 | 622 | 685 | 659 | 660 | Unmea- | 637 |
| | | | | | | | sured | |
| Ts [° C.] | 938 | 964 | 960 | 974 | 987 | 1,028 | Unmea- | Unmea- |
| | | | | | | | sured | sured |
| 10^{4.0} dPa · s [° C.] | 1,334 | 1,344 | 1,316 | 1,365 | 1,296 | 1,374 | Unmea- | 1,280 |
| | | | | | | | sured | |
| 10^{3.0} dPa · s [° C.] | 1,536 | 1,539 | 1,506 | 1,549 | 1,477 | 1,569 | Unmea- | 1,478 |
| | | | | | | | sured | |
| 10^{2.5} dPa · s [° C.] | 1,659 | 1,656 | 1,624 | 1,664 | 1,588 | 1,687 | Unmea- | 1,599 |
| | | | | | | | sured | |
| E [GPa] | Unmea- | Unmea- | Unmea- | Unmea- | Unmea- | Unmea- | Unmea- | Unmea- |
| | sured | sured | sured | sured | sured | sured | sured | sured |
| TL [° C.] | Unmea- | Unmea- | Unmea- | Unmea- | Unmea- | Unmea- | Unmea- | Unmea- |
| | sured | sured | sured | sured | sured | sured | sured | sured |
| logηTL [dPa · s] | Unmea- | Unmea- | Unmea- | Unmea- | Unmea- | Unmea- | Unmea- | Unmea- |
| | sured | sured | sured | sured | sured | sured | sured | sured |
| β-OH [mm⁻¹] | Unmea- | Unmea- | Unmea- | Unmea- | Unmea- | Unmea- | Unmea- | Unmea- |
| | sured | sured | sured | sured | sured | sured | sured | sured |
| Transmittance at 265 nm and | 66 | 43 | 46 | 48 | 66 | 43 | Unmea- | 23 |
| thickness of 1 mm [%] | | | | | | | sured | |
| Transmittance at 305 nm and | 83 | 82 | 85 | 71 | 81 | 85 | Unmea- | 69 |
| thickness of 1 mm [%] | | | | | | | sured | |
| Transmittance at 355 nm and | 91 | 91 | 91 | 89 | 90 | 91 | Unmea- | 86 |
| thickness of 1 mm [%] | | | | | | | sured | |
| Transmittance at 365 nm and | 91 | 91 | 91 | 90 | 91 | 91 | Unmea- | 87 |
| thickness of 1 mm [%] | | | | | | | sured | |
| Transmittance at 1,100 nm and | 93 | 93 | 93 | 93 | Unmea- | Unmea- | Unmea- | Unmea- |
| thickness of 1 mm [%] | | | | | sured | sured | sured | sured |
| Specific dielectric constant | 4.09 | 4.26 | 4.14 | 4.40 | 4.35 | 4.11 | Unmea- | 4.38 |
| (25° C., 2.45 GHz) | | | | | | | sured | |
| Dielectric dissipation factor | 0.00090 | 0.00124 | 0.00098 | 0.00159 | 0.00145 | 0.00117 | Unmea- | 0.00133 |
| (25° C., 2.45 GHz) | | | | | | | sured | |
| Specific dielectric constant | Unmea- | Unmea- | Unmea- | Unmea- | Unmea- | Unmea- | Unmea- | Unmea- |
| (25° C., 10 GHz) | sured | sured | sured | sured | sured | sured | sured | sured |
| Dielectric dissipation factor | Unmea- | Unmea- | Unmea- | Unmea- | Unmea- | Unmea- | Unmea- | Unmea- |
| (25° C., 10 GHz) | sured | sured | sured | sured | sured | sured | sured | sured |
| Processing accuracy of through | ∘ | ∘ | ∘ | ∘ | ∘ | ∘ | Unmea- | ∘ |
| holes | | | | | | | sured | |

TABLE 12

| | | No. 89 | No. 90 | No. 91 | No. 92 | No. 93 | No. 94 | No. 95 | No. 96 |
|---|---|---|---|---|---|---|---|---|---|
| Composition | SiO₂ | 71.12 | 62.60 | 64.60 | 66.32 | 60.34 | 58.34 | 64.35 | 62.83 |
| (mass %) | Al₂O₃ | 6.5 | 10.3 | 7.1 | 7.0 | 10.2 | 13.4 | 12.8 | 12.9 |
| | B₂O₃ | 17.5 | 23.0 | 24.2 | 22.6 | 25.4 | 24.2 | 18.2 | 19.6 |
| | Na₂O | 0.02 | 0.04 | 0.02 | 0.02 | 0.03 | 0.04 | 0.04 | 0.04 |
| | K₂O | 0.002 | 0.002 | 0.002 | 0.002 | 0.002 | 0.003 | 0.003 | 0.002 |
| | MgO | 1.98 | 0.48 | 0.48 | 0.48 | 0.47 | 0.48 | 0.66 | 0.66 |
| | CaO | 2.67 | 3.57 | 3.59 | 3.57 | 3.55 | 3.53 | 3.94 | 3.96 |
| | SrO | 0.000 | 0.000 | 0.000 | 0.000 | 0.000 | 0.000 | 0.000 | 0.000 |
| | BaO | 0.00 | 0.00 | 0.00 | 0.00 | 0.00 | 0.00 | 0.00 | 0.00 |
| | ZrO₂ | 0.00 | 0.00 | 0.00 | 0.00 | 0.00 | 0.00 | 0.00 | 0.00 |
| | TiO₂ | 0.000 | 0.000 | 0.000 | 0.000 | 0.000 | 0.001 | 0.000 | 0.000 |
| | SnO₂ | 0.20 | 0.00 | 0.00 | 0.00 | 0.00 | 0.00 | 0.00 | 0.00 |
| | Fe₂O₃ | 0.005 | 0.006 | 0.005 | 0.005 | 0.005 | 0.006 | 0.006 | 0.006 |

| | | | | | | | | |
|---|---|---|---|---|---|---|---|---|
| Mg + Ca + Sr + Ba | 4.65 | 4.05 | 4.07 | 4.05 | 4.02 | 4.01 | 4.60 | 4.62 |
| (Mg + Ca + Sr + Ba)/Al | 0.72 | 0.39 | 0.57 | 0.58 | 0.39 | 0.30 | 0.36 | 0.36 |
| B − (Mg + Ca + Sr + Ba) | 12.9 | 19.0 | 20.1 | 18.6 | 21.4 | 20.2 | 13.6 | 15.0 |
| (Mg + Ca + Sr + Ba)/ | 0.049 | 0.042 | 0.042 | 0.042 | 0.042 | 0.042 | 0.048 | 0.048 |
| (Si + Al + B) | | | | | | | | |
| B − Al | 11.0 | 12.7 | 17.1 | 15.6 | 15.2 | 10.8 | 5.4 | 6.7 |
| Li + Na + K | 0.022 | 0.042 | 0.022 | 0.022 | 0.032 | 0.043 | 0.043 | 0.042 |
| (Sr + Ba)/B | 0.000 | 0.000 | 0.000 | 0.000 | 0.000 | 0.000 | 0.000 | 0.000 |
| B/(Sr + Ba) | ∞ | ∞ | ∞ | ∞ | ∞ | ∞ | ∞ | ∞ |
| (Sr + Ba)/(Mg + Ca) | 0.000 | 0.000 | 0.000 | 0.000 | 0.000 | 0.000 | 0.000 | 0.000 |
| ρ [g/cm³] | Unmea- | Unmea- | Unmea- | Unmea- | 2.20 | 2.23 | 2.25 | 2.25 |
| | sured | sured | sured | sured | | | | |
| α(20-200° C.) [×10⁻⁷/° C.] | 26.9 | 30.1 | 31.4 | 30.3 | 32.0 | 30.9 | 27.2 | 28.2 |
| α(20-220° C.) [×10⁻⁷/° C.] | 26.9 | 30.1 | 31.3 | 30.2 | 31.9 | 31.0 | 27.3 | 28.3 |
| α(20-260° C.) [×10⁻⁷/° C.] | 26.7 | 30.0 | 31.1 | 30.0 | 31.8 | 31.0 | 27.4 | 28.4 |
| α(20-300° C.) [×10⁻⁷/° C.] | 26.6 | 29.9 | 30.9 | 29.8 | 31.7 | 31.0 | 27.5 | 28.4 |
| α(30-380° C.) [×10⁻⁷/° C.] | 26.2 | 29.6 | 30.3 | 29.2 | 31.3 | 30.9 | 27.6 | 28.4 |
| α(20-300° C.) − α(20-200° C.) | −0.3 | −0.2 | −0.5 | −0.5 | −0.3 | 0.1 | 0.3 | 0.2 |
| [×10⁻⁷/° C.] | | | | | | | | |
| Ps [° C.] | 616 | 582 | 561 | 573 | 567 | 585 | 623 | 616 |
| Ta [° C.] | 696 | 640 | 622 | 636 | 624 | 640 | 682 | 674 |
| Ts [° C.] | Unmea- | Unmea- | Unmea- | Unmea- | Unmea- | 963 | Unmea- | Unmea- |
| | sured | sured | sured | sured | sured | | sured | sured |
| 10^{4.0} dPa · s [° C.] | 1,434 | 1,316 | 1,358 | 1,385 | 1,279 | 1,252 | 1,334 | 1,309 |
| 10^{3.0} dPa · s [° C.] | 1,638 | 1,507 | 1,564 | 1,588 | 1,468 | 1,428 | 1,521 | 1,491 |
| 10^{2.5} dPa · s [° C.] | 1,774 | 1,625 | 1,678 | 1,717 | 1,583 | 1,539 | 1,634 | 1,603 |
| E [GPa] | Unmea- | Unmea- | Unmea- | Unmea- | Unmea- | Unmea- | Unmea- | Unmea- |
| | sured | sured | sured | sured | sured | sured | sured | sured |
| TL [° C.] | Unmea- | Unmea- | Unmea- | Unmea- | Unmea- | Unmea- | Unmea- | Unmea- |
| | sured | sured | sured | sured | sured | sured | sured | sured |
| logηTL [dPa · s] | Unmea- | Unmea- | Unmea- | Unmea- | Unmea- | Unmea- | Unmea- | Unmea- |
| | sured | sured | sured | sured | sured | sured | sured | sured |
| β-OH [mm⁻¹] | Unmea- | Unmea- | Unmea- | Unmea- | Unmea- | Unmea- | Unmea- | Unmea- |
| | sured | sured | sured | sured | sured | sured | sured | sured |
| Transmittance at 265 nm and | Unmea- | 26 | 55 | 51 | 30 | 24 | 25 | 25 |
| thickness of 1 mm [%] | sured | | | | | | | |
| Transmittance at 305 nm and | Unmea- | 55 | 77 | 76 | 58 | 52 | 54 | 54 |
| thickness of 1 mm [%] | sured | | | | | | | |
| Transmittance at 355 nm and | Unmea- | 86 | 91 | 90 | 87 | 86 | 87 | 86 |
| thickness of 1 mm [%] | sured | | | | | | | |
| Transmittance at 365 nm and | Unmea- | 88 | 91 | 91 | 89 | 88 | 89 | 88 |
| thickness of 1 mm [%] | sured | | | | | | | |
| Transmittance at 1,100 nm and | Unmea- | Unmea- | Unmea- | Unmea- | Unmea- | Unmea- | Unmea- | Unmea- |
| thickness of 1 mm [%] | sured | sured | sured | sured | sured | sured | sured | sured |
| Specific dielectric constant | 4.22 | 4.22 | 4.11 | 4.12 | 4.20 | 4.32 | 4.39 | 4.38 |
| (25° C., 2.45 GHz) | | | | | | | | |
| Dielectric dissipation factor | 0.00118 | 0.00118 | 0.00095 | 0.00095 | 0.00109 | 0.00131 | 0.00158 | 0.00150 |
| (25° C., 2.45 GHz) | | | | | | | | |
| Specific dielectric constant | Unmea- | Unmea- | Unmea- | Unmea- | Unmea- | Unmea- | Unmea- | Unmea- |
| (25° C., 10 GHz) | sured | sured | sured | sured | sured | sured | sured | sured |
| Dielectric dissipation factor | Unmea- | Unmea- | Unmea- | Unmea- | Unmea- | Unmea- | Unmea- | Unmea- |
| (25° C., 10 GHz) | sured | sured | sured | sured | sured | sured | sured | sured |
| Processing accuracy of through | ∘ | ∘ | ∘ | ∘ | ∘ | ∘ | ∘ | ∘ |
| holes | | | | | | | | |

TABLE 13

| | | No. 97 | No. 98 | No. 99 | No. 100 | No. 101 | No. 102 | No. 103 | No. 104 |
|---|---|---|---|---|---|---|---|---|---|
| Composition | SiO₂ | 64.96 | 64.52 | 63.00 | 61.89 | 62.51 | 63.18 | 61.07 | 60.70 |
| (mass %) | Al₂O₃ | 7.1 | 7.1 | 6.9 | 6.7 | 7.0 | 7.1 | 6.8 | 6.7 |
| | B₂O₃ | 26.1 | 25.9 | 25.5 | 24.9 | 25.4 | 25.4 | 24.4 | 23.2 |
| | Na₂O | 0.02 | 0.02 | 0.03 | 0.03 | 0.03 | 0.03 | 0.02 | 0.03 |
| | K₂O | 0.003 | 0.003 | 0.003 | 0.004 | 0.002 | 0.004 | 0.003 | 0.002 |
| | MgO | 1.77 | 0.02 | 0.00 | 0.00 | 2.39 | 0.05 | 0.00 | 0.71 |
| | CaO | 0.04 | 2.43 | 0.03 | 0.02 | 0.02 | 4.23 | 0.02 | 0.01 |
| | SrO | 0.000 | 0.000 | 4.470 | 0.010 | 0.020 | 0.000 | 7.610 | 0.020 |
| | BaO | 0.00 | 0.00 | 0.05 | 6.44 | 2.62 | 0.00 | 0.07 | 8.62 |
| | ZrO₂ | 0.00 | 0.00 | 0.00 | 0.00 | 0.00 | 0.00 | 0.00 | 0.00 |
| | TiO₂ | 0.000 | 0.000 | 0.009 | 0.000 | 0.000 | 0.000 | 0.000 | 0.001 |
| | SnO₂ | 0.00 | 0.00 | 0.00 | 0.00 | 0.00 | 0.00 | 0.00 | 0.00 |
| | Fe₂O₃ | 0.004 | 0.004 | 0.003 | 0.003 | 0.004 | 0.005 | 0.004 | 0.003 |

| | | | | | | | | |
|---|---|---|---|---|---|---|---|---|
| Mg + Ca + Sr + Ba | 1.81 | 2.45 | 4.55 | 6.47 | 5.05 | 4.28 | 7.70 | 9.36 |
| (Mg + Ca + Sr + Ba)/Al | 0.25 | 0.35 | 0.66 | 0.97 | 0.72 | 0.60 | 1.13 | 1.40 |
| B − (Mg + Ca + Sr + Ba) | 24.3 | 23.5 | 21.0 | 18.4 | 20.4 | 21.1 | 16.7 | 13.8 |
| (Mg + Ca + Sr + Ba)/ | 0.018 | 0.025 | 0.048 | 0.069 | 0.053 | 0.045 | 0.083 | 0.103 |
| (Si + Al + B) | | | | | | | | |
| B − Al | 19.0 | 18.8 | 18.6 | 18.2 | 18.4 | 18.3 | 17.6 | 16.5 |
| Li + Na + K | 0.023 | 0.023 | 0.033 | 0.034 | 0.032 | 0.034 | 0.023 | 0.032 |
| (Sr + Ba)/B | 0.000 | 0.000 | 0.177 | 0.259 | 0.104 | 0.000 | 0.315 | 0.372 |
| B/(Sr + Ba) | ∞ | ∞ | 6 | 4 | 10 | ∞ | 3 | 3 |
| (Sr + Ba)/(Mg + Ca) | 0.000 | 0.000 | 151 | 323 | 1.095 | 0.000 | 384 | 12 |
| ρ [g/cm³] | 2.14 | 2.15 | 2.19 | 2.22 | 2.20 | 2.18 | 2.25 | 2.27 |
| α(20-200° C.) [×10⁻⁷/° C.] | 30.8 | 31.5 | 32.4 | 33.4 | 31.8 | 32.6 | 34.4 | 34.4 |
| α(20-220° C.) [×10⁻⁷/° C.] | 30.6 | 31.4 | 32.3 | 33.2 | 31.7 | 32.5 | 34.3 | 34.4 |
| α(20-260° C.) [×10⁻⁷/° C.] | 30.3 | 31.1 | 32.0 | 32.9 | 31.4 | 32.3 | 34.1 | 34.2 |
| α(20-300° C.) [×10⁻⁷/° C.] | 29.9 | 30.7 | 31.6 | 32.6 | 31.2 | 32.0 | 33.8 | 33.9 |
| α(30-380° C.) [×10⁻⁷/° C.] | 29.1 | 29.9 | 30.8 | 31.8 | 30.5 | 31.5 | 33.3 | 33.3 |
| α(20-300° C.) − α(20-200° C.) | −0.9 | −0.8 | −0.8 | −0.8 | −0.6 | −0.6 | −0.6 | −0.5 |
| [×10⁻⁷/° C.] | | | | | | | | |
| Ps [° C.] | 520 | 534 | 525 | 518 | 549 | 562 | 547 | 536 |
| Ta [° C.] | 596 | 598 | 588 | 580 | 611 | 620 | 605 | 594 |
| Ts [° C.] | Unmea- | 926 | 927 | 943 | Unmea- | Unmea- | 903 | 899 |
| | sured | | | | sured | sured | | |
| 10^{4.0} dPa · s [° C.] | 1,348 | 1,369 | 1,373 | 1,379 | 1,333 | 1,334 | 1,330 | 1,340 |
| 10^{3.0} dPa · s [° C.] | 1,551 | 1,579 | 1,586 | 1,596 | 1,531 | 1,536 | 1,539 | 1,550 |
| 10^{2.5} dPa · s [° C.] | 1,670 | 1,706 | 1,712 | 1,728 | 1,652 | 1,654 | 1,666 | 1,670 |
| E [GPa] | Unmea- | Unmea- | Unmea- | Unmea- | Unmea- | Unmea- | Unmea- | Unmea- |
| | sured | sured | sured | sured | sured | sured | sured | sured |
| TL [° C.] | Unmea- | Unmea- | Unmea- | Unmea- | Unmea- | Unmea- | Unmea- | Unmea- |
| | sured | sured | sured | sured | sured | sured | sured | sured |
| logηTL [dPa · s] | Unmea- | Unmea- | Unmea- | Unmea- | Unmea- | Unmea- | Unmea- | Unmea- |
| | sured | sured | sured | sured | sured | sured | sured | sured |
| β-OH [mm⁻¹] | Unmea- | Unmea- | Unmea- | Unmea- | Unmea- | Unmea- | Unmea- | Unmea- |
| | sured | sured | sured | sured | sured | sured | sured | sured |
| Transmittance at 265 nm and | 35 | 29 | 41 | 40 | Unmea- | 19 | 38 | 36 |
| thickness of 1 mm [%] | | | | | sured | | | |
| Transmittance at 305 nm and | 61 | 57 | 66 | 66 | Unmea- | 54 | 69 | 67 |
| thickness of 1 mm [%] | | | | | sured | | | |
| Transmittance at 355 nm and | 88 | 87 | 89 | 89 | Unmea- | 88 | 89 | 89 |
| thickness of 1 mm [%] | | | | | sured | | | |
| Transmittance at 365 nm and | 90 | 89 | 90 | 90 | Unmea- | 89 | 90 | 90 |
| thickness of 1 mm [%] | | | | | sured | | | |
| Transmittance at 1,100 nm and | Unmea- | Unmea- | Unmea- | Unmea- | Unmea- | Unmea- | Unmea- | Unmea- |
| thickness of 1 mm [%] | sured | sured | sured | sured | sured | sured | sured | sured |
| Specific dielectric constant | 3.90 | 3.98 | 4.02 | 4.08 | 4.06 | 4.14 | 4.21 | 4.25 |
| (25° C., 2.45 GHz) | | | | | | | | |
| Dielectric dissipation factor | 0.00070 | 0.00072 | 0.00073 | 0.00076 | 0.00093 | 0.00097 | 0.00094 | 0.00096 |
| (25° C., 2.45 GHz) | | | | | | | | |
| Specific dielectric constant | Unmea- | Unmea- | Unmea- | Unmea- | Unmea- | Unmea- | Unmea- | Unmea- |
| (25° C., 10 GHz) | sured | sured | sured | sured | sured | sured | sured | sured |
| Dielectric dissipation factor | Unmea- | Unmea- | Unmea- | Unmea- | Unmea- | Unmea- | Unmea- | Unmea- |
| (25° C., 10 GHz) | sured | sured | sured | sured | sured | sured | sured | sured |
| Processing accuracy of through | ∘ | ∘ | ∘ | ∘ | ∘ | ∘ | ∘ | ∘ |
| holes | | | | | | | | |

Samples No. 1 to 104 were produced in the following manner. First, glass raw materials blended so as to have a glass composition in any one of the tables were placed in a platinum crucible, and melted at 1,600° C. for 24 hours. After that, the molten glass was poured out on a carbon sheet so as to be formed into a flat sheet shape. The resultant glass sheet having a thickness of 0.5 mm was processed into various measurement samples, and surfaces thereof were ground and polished. Thus, a glass film having a thickness of 0.045 mm was obtained. The arithmetic average roughness Ra of the surface of the resultant glass film was measured with a stylus-type surface roughness meter and found to be 400 nm. Next, each of the resultant samples was evaluated for its density ρ, thermal expansion coefficients α in various temperature ranges, strain point Ps, annealing point Ta, softening point Ts, temperature at 10^{4.0} dPa·s, temperature at 10^{3.0} dPa·s, temperature at 10^{2.5} dPa·s, Young's modulus E, liquidus temperature TL, liquidus viscosity log ηTL, specific dielectric constant at 25° C. and a frequency of 2.45 GHz, dielectric dissipation factor at 25° C. and a frequency of 2.45 GHz, specific dielectric constant at 25° C. and a frequency of 10 GHz, dielectric dissipation factor at 25° C. and a frequency of 10 GHz, external transmittances at various wavelengths in terms of a thickness of 1.0 mm, and processing accuracy of through holes. SnO₂ was used as a fining agent in this Example, but a fining agent other than SnO₂ may be used. In addition, when bubbles are satisfactorily removed by adjusting the melting conditions and the glass batch, no fining agent needs to be added.

The density ρ is a value measured by a well-known Archimedes method.

The thermal expansion coefficients α in various temperature ranges are values measured with a dilatometer.

The strain point Ps, the annealing point Ta, and the softening point Ts are values measured based on methods of ASTM C336 and C338.

The temperature at 10^{4.0} dPa·s, the temperature at 10^{3.0} dPa·s, and the temperature at 10^{2.5} dPa·s are values measured by a platinum sphere pull up method.

The Young's modulus E is a value measured by a resonance method.

The liquidus temperature TL is a value obtained by measuring a temperature at which a crystal precipitates after glass powder that passes through a standard 30-mesh sieve (500 μm) and remains on a 50-mesh sieve (300 μm) is placed in a platinum boat and kept in a gradient heating furnace for 24 hours.

The liquidus viscosity log ηTL is a value obtained by measuring the viscosity of glass at its liquidus temperature TL by a platinum sphere pull up method.

The specific dielectric constant and the dielectric dissipation factor at 25° C. and a frequency of 2.45 GHz, and the specific dielectric constant and the dielectric dissipation factor at 25° C. and a frequency of 10 GHz refer to values measured by a well-known cavity resonator method.

The external transmittances at various wavelengths in terms of a thickness of 1.0 mm refer to values measured with a commercially available spectrophotometer (e.g., V-670 manufactured by JASCO Corporation) using a measurement sample obtained by polishing both surfaces into optically polished surfaces (mirror surfaces).

The processing accuracy of through holes was evaluated as follows: a case in which a difference between the maximum value and the minimum value of the inner diameters of through holes formed by processing each sample (thickness: 0.5 mm) under the same conditions was less than 50 μm was marked with Symbol “0”; and a case in which the difference between the maximum value and the minimum value of the inner diameters was 50 μm or more was marked with Symbol “x”.

### Example 2

A glass batch blended so as to have the glass composition of Sample No. 19 shown in Table 3 was melted in a test melting furnace to provide molten glass, followed by forming thereof into a glass film having a thickness of 0.045 mm by an overflow down-draw method. In the forming of the glass film, the speed of drawing rollers, the speed of cooling rollers, the temperature distribution of a heating apparatus, the temperature of the molten glass, the flow rate of the molten glass, a sheet-drawing speed, the rotation number of a stirrer, and the like were appropriately adjusted to control the thermal shrinkage rate, total thickness variation (TTV), and warpage of the glass film. Next, the resultant glass film was cut to provide a glass film having a rectangular shape measuring 200 mm×200 mm. Next, the arithmetic average roughness Ra of the surface of the resultant glass film was measured with an atomic force microscope (AFM) and found to be 0.2 nm.

### Example 3

Glass batches blended so as to have the glass compositions of Sample No. 19 shown in Table 3 and Sample No. 72 shown in Table 9 were each melted in a test melting furnace to provide molten glass, followed by forming thereof into a glass film having a thickness of 0.03 mm by an overflow down-draw method. Next, the arithmetic average roughness Ra of the surface of the resultant glass film was measured with an atomic force microscope (AFM) and found to be 0.3 nm. Next, the resultant glass film was cut to provide a glass film having a rectangular shape measuring 300 mm×400 mm. Next, a plurality of through holes were formed in the glass film having a rectangular shape. The through holes were produced by irradiating the surface of the glass film with a commercially available picosecond laser to form a modification layer, and then removing the modification layer by etching. The inner diameters of the through holes according to each of Sample No. 19 and Sample No. 91 were measured. In both cases, the maximum value was 85 μm, the minimum value was 62 μm, and the difference between the maximum value and the minimum value of the inner diameters was 23 μm. In addition, in both cases, the maximum length of a crack in a surface direction extending from the through holes was 2 μm.

Next, a high-frequency device was produced with each of the glass films according to Sample No. 19 and Sample No. 72. First, for the through holes of the glass film, a conductor circuit layer was formed by a semi-additive method. Specifically, the conductor circuit layer was formed by sequentially performing the production of a seed metal layer by a sputtering method, the formation of a metal layer by an electroless plating method, the formation of a resist pattern, and the formation of copper plating for wiring.

Subsequently, a capacitor, a coil, and the like were arranged on both surfaces of the glass film, an insulating resin layer was then formed, and via holes were produced. After that, desmear treatment and electroless copper plating treatment were performed, and further, a dry film resist layer was formed. A resist pattern was formed by photolithography, and then a conductor circuit layer was formed by a copper electroplating method. After that, the formation of a multilayer circuit was repeated to form build-up multilayer circuits on both surfaces of the glass film (glass core).

Further, for the outermost layer of the multilayer circuits, a solder resist layer was formed, an external connection terminal portion was exposed by photolithography, and plating was performed, followed by the formation of solder balls. The step of forming the solder balls had the highest heat treatment temperature among the series of steps, which was about 320° C. Finally, the glass film having the solder balls formed thereon was subjected to dicing processing to provide a high-frequency device.

### Example 4

A glass batch blended so as to have the glass composition of Sample No. 19 shown in Table 3 was melted in a test melting furnace to provide molten glass, followed by forming thereof into a glass film having a thickness of 0.045 mm by an overflow down-draw method. In the forming of the glass film, the speed of drawing rollers, the speed of cooling rollers, the temperature distribution of a heating apparatus, the temperature of the molten glass, the flow rate of the molten glass, a sheet-drawing speed, the rotation number of a stirrer, and the like were appropriately adjusted to control the thermal shrinkage rate, total thickness variation (TTV), and warpage of the glass film. Next, the resultant glass film was taken up into a roll shape to provide a glass roll having a radius of curvature of 60 mm, a roll outer diameter of 500 mm, and a roll width of 700 mm.

### Example 5

Glass batches for achieving the glass compositions of Sample No. 19 shown in Table 3 and Sample No. 72 shown in Table 9 were each melted in a test melting furnace to provide molten glass, followed by forming thereof into a glass sheet having a thickness of 0.3 mm by an overflow down-draw method.

Next, the resultant glass sheet was cut to provide a glass sheet having a rectangular shape measuring 350 mm×450 mm. The glass sheet was subjected to polishing processing until its thickness became 0.09 mm to provide a glass film. The arithmetic average roughness Ra of the glass film after the polishing processing was measured with a stylus-type surface roughness meter and found to be 500 nm. Next, a plurality of through holes were formed in the glass film having a rectangular shape. The through holes were produced by irradiating the surface of the glass film with a commercially available picosecond laser to form a modification layer, and then removing the modification layer by etching.

Next, a high-frequency device was produced with each of the glass films according to Sample No. 19 and Sample No. 72. First, for the through holes of the glass film, a conductor circuit layer was formed by a semi-additive method. Specifically, the conductor circuit layer was formed by sequentially performing the production of a seed metal layer by a sputtering method, the formation of a metal layer by an electroless plating method, the formation of a resist pattern, and the formation of copper plating for wiring.

Subsequently, a capacitor, a coil, and the like were arranged on both surfaces of the glass film, an insulating resin layer was then formed, and via holes were produced. After that, desmear treatment and electroless copper plating treatment were performed, and further, a dry film resist layer was formed. A resist pattern was formed by photolithography, and then a conductor circuit layer was formed by a copper electroplating method. After that, the formation of a multilayer circuit was repeated to form build-up multilayer circuits on both surfaces of the glass film (glass core). Peeling of the circuit layer did not occur in this step.

Further, for the outermost layer of the multilayer circuits, a solder resist layer was formed, an external connection terminal portion was exposed by photolithography, and plating was performed, followed by the formation of solder balls. The step of forming the solder balls had the highest heat treatment temperature among the series of steps, which was about 320° C. Finally, the glass film having the solder balls formed thereon was subjected to dicing processing to provide a high-frequency device.

### INDUSTRIAL APPLICABILITY

The glass film and the glass roll using the same of the present invention are suitable as a substrate for a high-frequency device, and besides, are also suitable as a substrate for a printed wiring board, a substrate for a flexible printed wiring board, a substrate for a glass antenna, a substrate for a micro-LED, and a substrate for a glass interposer, each of which is required to have low dielectric characteristics. In addition, the glass film and the glass roll using the same of the present invention may also be used as a constituent member of a resonator of a dielectric filter, such as a duplexer.

1. A glass film, which has a film thickness of 100 μm or less, wherein the glass film has a specific dielectric constant at 25° C. and a frequency of 2.45 GHz of 5 or less and a dielectric dissipation factor at 25° C. and a frequency of 2.45 GHz of 0.01 or less.

2. A glass film, which has a film thickness of 100 μm or less, wherein the glass film has a specific dielectric constant at 25° C. and a frequency of 10 GHz of 5 or less and a dielectric dissipation factor at 25° C. and a frequency of 10 GHz of 0.01 or less.

3. The glass film according to claim 1, wherein the glass film has a film thickness of less than 50 μm.

4. The glass film according to claim 1, wherein the glass film comprises as a glass composition, in terms of mass %, 50% to 72% of SiO₂, 0% to 22% of Al₂O₃, 15% to 38% of B₂O₃, 0% to 3% of Li₂O+Na₂O+K₂O, and 0% to 12% of MgO+CaO+SrO+BaO.

5. The glass film according to claim 4, wherein the glass film comprises as the glass composition, in terms of mass %, 50% to 72% of SiO₂, 0.3% to 10.9% of Al₂O₃, 18.1% to 38% of B₂O₃, 0.001% to 3% of Li₂O+Na₂O+K₂O, and 0% to 12% of MgO+CaO+SrO+BaO.

6. The glass film according to claim 1, wherein the glass film has a mass ratio (MgO+CaO+SrO+BaO)/(SiO₂+Al₂O₃+B₂O₃) of from 0.001 to 0.4.

7. The glass film according to claim 1, wherein the glass film has a plurality of through holes formed in a thickness direction.

8. The glass film according to claim 7, wherein the through holes have an average inner diameter of 300 μm or less.

9. The glass film according to claim 7, wherein a difference between a maximum value and a minimum value of inner diameters of the through holes is 50 μm or less.

10. The glass film according to claim 7, wherein a maximum length of a crack in a surface direction extending from the through holes is 100 μm or less.

11. The glass film according to claim 1, wherein the glass film has a Young's modulus of 70 GPa or less.

12. The glass film according to claim 1, wherein the glass film has a thermal shrinkage rate of 30 ppm or less in a case in which the glass film is increased in temperature at a rate of 5° C./min, kept at 500° C. for 1 hour, and decreased in temperature at a rate of 5° C./min.

13. The glass film according to claim 1, wherein the glass film has a thermal expansion coefficient in a temperature range of from 30° C. to 380° C. of from 20×10⁻⁷/° C. to 50×10⁻⁷/° C.

14. The glass film according to claim 1, wherein the glass film has a value obtained by subtracting a thermal expansion coefficient in a temperature range of from 20° C. to 200° C. from a thermal expansion coefficient in a temperature range of from 20° C. to 300° C. of 1.0×10⁻⁷/° C. or less.

15. The glass film according to claim 1, wherein the glass film has an external transmittance at a wavelength of 355 nm in terms of a thickness of 1.0 mm of 80% or more.

16. The glass film according to claim 1, wherein the glass film has an external transmittance at a wavelength of 265 nm in terms of a thickness of 1.0 mm of 15% or more.

17. The glass film according to claim 1, wherein the glass film has a liquidus viscosity of 10^{4.0} dPa·s or more.

18. The glass film according to claim 1, wherein the glass film is formed by an overflow down-draw method.

19. The glass film according to claim 1, wherein the glass film is used as a substrate for a high-frequency device.

20. A glass roll, which is obtained by taking up a glass film into a roll shape, wherein the glass film is the glass film of claim 1.
